(19) United States
(12) Patent Application Publication
(10) Pub. No.: US 2024/0256976 A1
(43) Pub. Date: Aug. 1, 2024

(54) METHOD FOR GENERATING ASSIST FEATURES USING MACHINE LEARNING MODEL

(71) Applicant: ASML NETHERLANDS B.V., Veldhoven (NL)

(72) Inventors: Jun TAO, Cupertino, CA (US); Yu CAO, Saratoga, CA (US); Christopher Alan SPENCE, Los Altos, CA (US)

(73) Assignee: ASML NETHERLANDS B.V., Veldhoven (NL)

(21) Appl. No.: 18/565,759

(22) PCT Filed: Jun. 10, 2022
(86) PCT No.: PCT/EP2022/065811

§ 371 Date: Nov. 30, 2023

Related U.S. Application Data
(60) Provisional application No. 63/212,434, filed on Jun. 18, 2021.

(51) Int. Cl. G06N 20/00; G03F 1/36

(52) U.S. Cl. CPC G06N 20/00; G03F 1/36

(57) ABSTRACT

Described herein is a method of determining assist features for a mask pattern. The method includes obtaining (i) a target pattern comprising a plurality of target features, wherein each of the plurality of target features comprises a plurality of target edges, and (ii) a trained sequence-to-sequence machine leaning (ML) model (e.g., long short term memory, Gated Recurrent Units, etc.) configured to determine sub-resolution assist features (SRAFs) for the target pattern. For a target edge of the plurality of target edges, geometric information (e.g., length, width, distances between features, etc.) of a subset of target features surrounding the target edge is determined. Using the geometric information as input, the ML model generates SRAFs to be placed around the target edge.

### CROSS-REFERENCE TO RELATED APPLICATIONS

This application claims priority of U.S. application 63/212,434 which was filed on 18 Jun. 2021, and which is incorporated herein in its entirety by reference.

### FIELD

The present disclosure relates to lithography technologies, and more particularly, to mechanisms of generating assist features for a target pattern that can be further used for generating a patterning device pattern.

### BACKGROUND

A lithography apparatus is a machine that transfers a desired pattern onto a target portion of a substrate. Lithography apparatus can be used, for example, in the manufacture of integrated circuits (ICs). In that circumstance, a patterning device, which is alternatively referred to as a mask or a reticle, may be used to generate a circuit pattern corresponding to an individual layer of the IC, and this pattern can be imaged onto a target portion (e.g., comprising part of, one or several dies) on a substrate (e.g., a silicon wafer) that has a layer of radiation-sensitive material (resist). In general, a single substrate contains a network of adjacent target portions that are successively exposed. Known lithography apparatus include so-called steppers, in which each target portion is irradiated by exposing an entire pattern onto the target portion in one go, and so-called scanners, in which each target portion is irradiated by scanning the pattern through the beam in a given direction (the “scanning”-direction) while synchronously scanning the substrate parallel or anti parallel to this direction.

Prior to transferring the circuit pattern from the patterning device to the substrate, the substrate may undergo various processes, such as priming, resist coating and a soft bake. After exposure, the substrate may be subjected to other processes, such as a post-exposure bake (PEB), development, a hard bake and measurement/inspection of the transferred circuit pattern. This array of processes is used as a basis to make an individual layer of a device, e.g., an IC device. The substrate may then undergo various processes to produce the individual layer of the device, such as etching, ion-implantation (doping), metallization, oxidation, chemo-mechanical polishing, etc. If several layers are required in the device, then the whole procedure, or a variant thereof, can be repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. The device manufacturing typically includes a patterning process. A patterning process involves a patterning step, such as optical and/or nanoimprint lithography using a patterning device (e.g., a mask) in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

### SUMMARY

Semiconductor manufacturing involves generating mask patterns so that nanoscale features of a circuit can be accurately printed on a substrate. Such mask patterns may be predicted using a trained machine learning model configured to generate assist features for building the mask patterns. However, for training purposes, ground truth data, e.g., generated using existing mask pattern generation processes, may comprise different assist features for similar patterns. When such inconsistent ground truth data is used for training, it may cause the machine learning model to predict averaged assist features. For example, a predicted feature may be an average of two possible predictions (e.g., cross shaped assist features). This can cause ambiguity in assist feature extraction thereby adversely affecting generation of the mask pattern. Some existent image-based assist feature generation approach tends to have grid dependency issues and may not incorporate MRC constraints.

According to the present disclosure, mechanisms are provided herein to train and use a sequence-to-sequence machine learning model to predict the assist features. The training data comprises geometric information of target features so that the trained model can predict properties of the assist features directly, thus advantageously avoiding the grid dependency issue, avoiding the averaging effect in convolutional neural network (CNN). It can significantly reduce ambiguity in creating assist features. Another advantages effect being the sequence-to-sequence model generated assist features when employed in a mask pattern create good process window (comparable to the ground truth data). Also, the runtime is better compared than current CNN-based training approaches.

In an embodiment, there is provided a method of training a machine learning model for generating assist features for a mask pattern. The method includes obtaining (i) a target pattern comprising a plurality of target features where each of the plurality of target features comprises a plurality of target edges, and (ii) a trained sequence-to-sequence machine leaning (ML) model configured to determine sub-resolution assist features (SRAFs) for the target pattern. For a target edge of the plurality of target edges, geometric information of a subset of target features surrounding the target edge is determined. Using the geometric information as input to the ML model, SRAFs to be placed around the target edge is determined.

In an embodiment, the ML model is a recurrent neural network configured to handle sequential input data. For example, the ML model is an encoder-decoder of a long short term memory architecture, an encoder-decoder of a gated recurrent unit architecture, or a transformer neural network.

In an embodiment, the method further involves partitioning, using each of the target edge as a reference, of the target pattern into a plurality of cells so that each cell includes a portion of a target edge of a target feature. For example, partitioning of the target pattern involves selecting a point on each edge of the plurality of target features; and dividing, based on the selected points, the target pattern into the plurality of cells. In an embodiment, partitioning is performed using the selected points as seeds to a Voronoi partitioning method to generate a plurality of Voronoi cells.

In an embodiment, the geometric information of the subset of target features that are at least partially within a subset of cells of the plurality of cells, is determined. For example, the subset of cells is within a desired range of the target edge within the target pattern. In an embodiment, determining of the geometric information involves identifying the subset of target features are within in a selected area around the target edge, where the selected area is a range of influence of neighboring target features on the SRAF generation for the target edge. In an embodiment, the geometric information may be distances between the target edge and each target feature of the subset of target features within the target pattern, a width, and/or a length of each target feature of the subset of target features, and/or a location of each target feature of the subset of target features.

In an embodiment, determining of the SRAFs involves determining, by the ML model, the geometry of assist features that satisfies mask rule check (MRC) constraints, wherein the ML model generates the SRAFs in a sequential manner such that an earlier SRAF having satisfied shaped constraint is used to generate subsequent SRAFs causing the generated SRAFs to automatically satisfies the MRC constraints.

In an embodiment, there is provided a method of training a sequence-to-sequence machine learning (ML) model to generate sub-resolution assist features (SRAFs) for a mask. The method involves obtaining training data comprising a target pattern having a plurality of target features, and ground truth data including reference sub-resolution assist features corresponding to the target pattern. For each target edge of the target pattern, geometric information (e.g., length, width, distance between target features, etc.) of a subset of target features surrounding a target edge under consideration is assigned. Using a sequence-to-sequence machine learning algorithm, the geometric information and the ground truth, a ML model is trained to generate SRAFs, in a sequential manner, to satisfy a matching threshold with respect to the reference SRAFs.

In an embodiment, training data is provided as input data or input vector to the ML model, the input data or the input vector comprises at least one of: sizes of the subset of target features, distances between the target edge under consideration and the subset of target features, and locations of the subset of target features.

In an embodiment, the method involves partitioning, using each of the target edge as a reference, of the target pattern into a plurality of cells so that each cell includes a portion of a target edge of a target feature. In an embodiment, partitioning of the target pattern involves selecting a point on each target edge of the plurality of target features; and dividing, based on the selected points, the target pattern into the plurality of cell. For example, the target pattern is partitioned using the selected points as seeds to a Voronoi partitioning method to generate a plurality of Voronoi cells.

In an embodiment, the method involves determining the geometric information of the subset of target features neighboring to the target edge under consideration, the subset of target features being within one or more cells surrounding the target edge under consideration; and generating an input vector comprising the geometric information associated with each of the target edges within the target pattern.

In an embodiment, determining of the geometric information involves identifying the subset of target features that are at least partially within the one or more cells in a selected area around the edge of interest, the selected area providing a range of influence of the neighboring target feature on the SRAF generation for the target edge under consideration.

In an embodiment, the training process involves providing the geometric information of the subset of target features to the ML model to predict in a sequence geometry of SRAFs for each target edge of the target pattern; and comparing the predict SRAFs with the one or more reference SRAFs related to respective target edges of the target pattern; and adjusting model parameters of the ML model to cause the predicted SRAFs to be within the matching threshold with respect to the reference SRAFS in the ground truth. In an embodiment, adjusting of the model parameters involves generating output from the ML model in a sequential manner for each target edge; comparing the generated output with the reference SRAFs to determine whether the generated output is within the matching threshold with respect to the reference SRAFs; and responsive to the generated output not matching the reference SRAFs, adjusting values of the model parameters to cause the output to be within the matching threshold.

In an embodiment, generating of the output involves determining, by the ML model, geometry of a first assist feature corresponding to a first reference SRAF of the reference SRAFs; determining, by the ML model based on the first assist feature, geometry of a second assist feature that correspond to a second reference SRAF of the reference SRAFs; and determining, by the ML model based on the first and second assist features, geometry of a third assist feature that correspond to a second reference SRAF of the reference SRAFs.

Furthermore, in an embodiment, there is provided a non-transitory computer-readable media comprising instructions that, when executed by one or more processors, cause operations including steps of the methods discussed above.

### BRIEF DESCRIPTION OF THE DRAWINGS

Embodiments will now be described, by way of example only, with reference to the accompanying drawings in which:

FIG. 1 shows a block diagram of various subsystems of a lithography system, according to an embodiment;

FIG. 2 depicts an example flow chart for modeling and/or simulating at least part of a patterning process, according to an embodiment;

FIGS. 3A and 3B illustrate an example grid dependency error related to simulating of a patterning process, according to an embodiment;

FIG. 4 is a flow chart for generating assist features for target patterns of a design layout, according to an embodiment;

FIG. 5 illustrates an exemplary partitioning of a target pattern of a design layout, according to an embodiment;

FIG. 6A illustrates an exemplary cell of the partitioned target pattern of FIG. 5, according to an embodiment;

FIG. 6B illustrates exemplary references assist features assigned to the target edge shown in FIG. 6A, according to an embodiment;

FIG. 6C illustrates selecting neighboring target features and geometric information associated therewith, according to an embodiment;

FIG. 7 an exemplary training of a long-short term memory model comprising an encoder and a decoder, the model being trained according to the method of FIG. 4, according to an embodiment;

FIG. 8 illustrates exemplary assist features generated by the trained machine learning model, according to an embodiment;

FIG. 9 is a flow chart of a method employing the trained machine learning model to generate assist features for any given target pattern of a design layout, according to an embodiment;

FIG. 10 is a block diagram of an exemplary computer system, according to an embodiment;

FIG. 11 is a diagram of an exemplary lithographic projection apparatus, according to an embodiment;

FIG. 12 is a diagram of an exemplary extreme ultraviolet (EUV) lithographic projection apparatus, according to an embodiment;

FIG. 13 is a more detailed view of the exemplary apparatus in FIG. 12, according to an embodiment; and

FIG. 14 is a more detailed view of the source collector module of the apparatus of FIG. 12 and FIG. 13, according to an embodiment.

### DETAILED DESCRIPTION

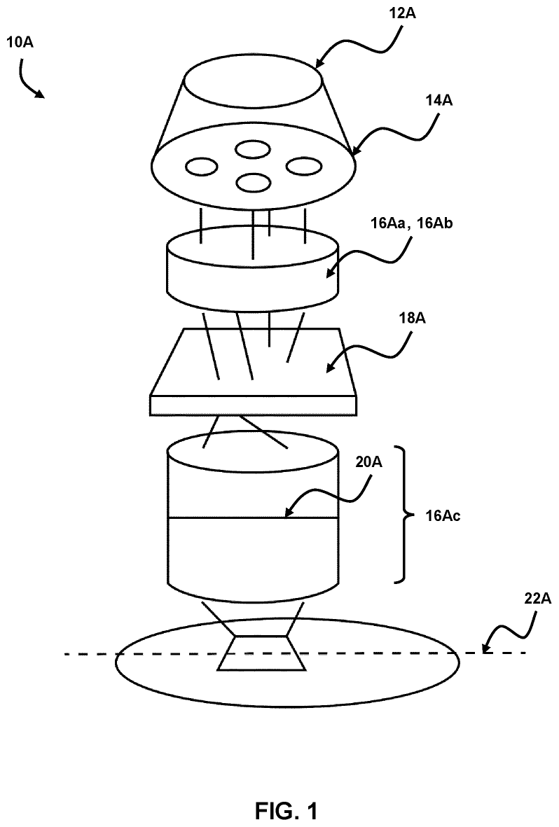

FIG. 1 illustrates an exemplary lithographic projection apparatus 10A in accordance with an embodiment of the present disclosure. The apparatus 10A includes a radiation source 12A, which may be a deep-ultraviolet (DUV) excimer laser source or other type of source including an extreme ultraviolet (EUV) source. However, as discussed above, in some other embodiments, the radiation source may not be an integral part of the lithographic projection apparatus itself. The apparatus 10A further includes: illumination optics which, e.g., define the partial coherence (denoted as sigma) and which may include optics 14A, 16Aa and 16Ab configured to shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(Θmax), wherein n is the refractive index of the media between the substrate and the last element of the projection optics, and Θmax is the largest angle of the beam exiting from the projection optics that can still impinge on the substrate plane 22A.

In a lithographic projection apparatus, a source provides illumination (i.e. radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist layer on the substrate is exposed and the aerial image is transferred to the resist layer as a latent “resist image” (RI) therein. The resist image (RI) can be defined as a spatial distribution of solubility of the resist in the resist layer. A resist model can be used to calculate the resist image from the aerial image, an example of which can be found in U.S. Patent Application Publication No. US 20090157360, the disclosure of which is hereby incorporated by reference in its entirety. The resist model is related to properties of the resist layer, e.g., effects of chemical processes which occur during exposure, PEB and development. Optical properties of the lithographic projection apparatus (e.g., properties of the source, the patterning device and the projection optics) dictate the aerial image. Since the patterning device used in the lithographic projection apparatus can be changed, it may be desirable to separate the optical properties of the patterning device from the optical properties of the rest of the lithographic projection apparatus including at least the source and the projection optics.

In an embodiment, assist features (e.g., sub resolution assist features and/or printable resolution assist features) may be placed into the design layout based on how the design layout is optimized according to the methods of the present disclosure. In an embodiment, a machine learning based model is used to determine a patterning device pattern. The machine learning model may be a neural network such as a sequence-to-sequence machine learning model that can be trained in a certain way to obtain accurate predictions at a fast rate, thus enabling a full-chip simulation of the patterning process.

A neural network may be trained (i.e., whose parameters are determined) using a set of training data. The training data may comprise or consist of a set of training samples. Each sample may be a pair of an input object (e.g., a vector, which may be called a feature vector) and a desired output value. A training algorithm analyzes the training data and adjusts the behavior of the neural network by adjusting the parameters (e.g., weights of one or more layers) of the neural network based on the training data. The neural network after training can be used for mapping new samples.

In an embodiment, machine learning models of the patterning process can be trained to predict, for example, contours, patterns, CDs for a mask pattern, and/or contours, CDs, edge placement (e.g., edge placement error), etc. in the resist and/or etched image on a wafer. An objective of the training is to enable accurate prediction of, for example, contours, aerial image intensity slope, and/or CD, etc. of the printed pattern on a wafer. The intended design (e.g., a wafer target layout to be printed on a wafer) is generally defined as a pre-Optical Proximity Correction (OPC) design layout which can be provided in a standardized digital file format such as GDSII or OASIS or other file format.

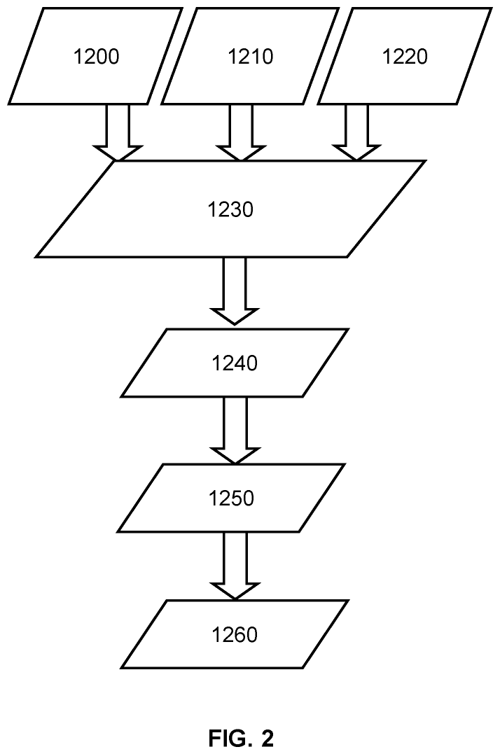

An exemplary flow chart for modelling and/or simulating parts of a patterning process is illustrated in FIG. 2. As will be appreciated, the models may represent a different patterning process and need not comprise all the models described below. A source model 1200 represents optical characteristics (including radiation intensity distribution, bandwidth and/or phase distribution) of the illumination of a patterning device. The source model 1200 can represent the optical characteristics of the illumination that include, but not limited to, numerical aperture settings, illumination sigma (6) settings as well as any particular illumination shape (e.g. off-axis radiation shape such as annular, quadrupole, dipole, etc.), where a (or sigma) is outer radial extent of the illuminator.

A projection optics model 1210 represents optical characteristics (including changes to the radiation intensity distribution and/or the phase distribution caused by the projection optics) of the projection optics. The projection optics model 1210 can represent the optical characteristics of the projection optics, including aberration, distortion, one or more refractive indexes, one or more physical sizes, one or more physical dimensions, etc.

The patterning device/design layout model module 1220 captures how the design features are laid out in the pattern of the patterning device and may include a representation of detailed physical properties of the patterning device, as described, for example, in U.S. Pat. No. 7,587,704, which is incorporated by reference in its entirety. In an embodiment, the patterning device/design layout model module 1220 represents optical characteristics (including changes to the radiation intensity distribution and/or the phase distribution caused by a given design layout) of a design layout (e.g., a device design layout corresponding to a feature of an integrated circuit, a memory, an electronic device, etc.), which is the representation of an arrangement of features on or formed by the patterning device. Since the patterning device used in the lithographic projection apparatus can be changed, it is desirable to separate the optical properties of the patterning device from the optical properties of the rest of the lithographic projection apparatus including at least the illumination and the projection optics. The objective of the simulation is often to accurately predict, for example, edge placements and CDs, which can then be compared against the device design. The device design is generally defined as the pre-OPC patterning device layout, which may be provided in a standardized digital file format such as GDSII or OASIS.

An aerial image 1230 can be simulated from the source model 1200, the projection optics model 1210 and the patterning device/design layout model 1220. An aerial image (AI) is the radiation intensity distribution at substrate level. Optical properties of the lithographic projection apparatus (e.g., properties of the illumination, the patterning device and the projection optics) dictate the aerial image.

A resist layer on a substrate is exposed by the aerial image and the aerial image is transferred to the resist layer as a latent “resist image” (RI) therein. The resist image (RI) can be defined as a spatial distribution of solubility of the resist in the resist layer. A resist image 1250 can be simulated from the aerial image 1230 using a resist model 1240. The resist model 1240 can be used to calculate the resist image from the aerial image, an example of which can be found in U.S. Patent Application Publication No. US 20090157360, the disclosure of which is hereby incorporated by reference in its entirety. The resist model typically describes the effects of chemical processes which occur during resist exposure, post exposure bake (PEB) and development, in order to predict, for example, contours of resist features formed on the substrate and so it typically related only to such properties of the resist layer (e.g., effects of chemical processes which occur during exposure, post-exposure bake and development). In an embodiment, the optical properties of the resist layer, e.g., refractive index, film thickness, propagation and polarization effects may be captured as part of the projection optics model 1210.

In general, the connection between the optical and the resist model is a simulated aerial image intensity within the resist layer, which arises from the projection of radiation onto the substrate, refraction at the resist interface and multiple reflections in the resist film stack. The radiation intensity distribution (aerial image intensity) is turned into a latent “resist image” by absorption of incident energy, which can be further modified by diffusion processes and various loading effects. Efficient simulation methods that are fast enough for full-chip applications approximate the realistic 3-dimensional intensity distribution in the resist stack by a 2-dimensional aerial (and resist) image.

In an embodiment, the resist image can be used an input to a post-pattern transfer process model module 1260. The post-pattern transfer process model 1260 defines performance of one or more post-resist development processes (e.g., etch, development, etc.).

Simulation of the patterning process can, for example, predict contours, CDs, edge placement (e.g., edge placement error), etc. in the resist and/or etched image. Thus, the objective of the simulation is to accurately predict, for example, edge placement, and/or aerial image intensity slope, and/or CD, etc. of the printed pattern. These values can be compared against an intended design to, e.g., correct the patterning process, identify where a defect is predicted to occur, etc. The intended design is generally defined as a pre-OPC design layout which can be provided in a standardized digital file format such as GDSII or OASIS or other file format.

Thus, the model formulation describes most, if not all, of the known physics and chemistry of the overall process, and each of the model parameters desirably corresponds to a distinct physical or chemical effect. The model formulation thus may set an upper bound on how well the model can be used to simulate the overall manufacturing process.

Continuous Transmission Mask (CTM) technique is an inverse lithography solution that can generate a grayscale guidance map for a mask pattern. Based on the grayscale guidance map, assist features and modifications to main features of a design layout can be extracted. In an embodiment, such guidance map can be used to generated polygon shaped features (e.g., main features, assist features, SRAFs, SERIFs, etc.). Masks manufactured using patterns generated using CTM+techniques are referred as curvilinear masks. In an embodiment, a CTM+technique involves determining a guidance map using a level-set method, where a level-set threshold values assist in determining the curved polygon shaped features (e.g., main features, assist features, SRAFs, SERIFs, etc.).

An example method of generating a curvilinear mask is discussed in PCT patent publication number WO 2019179747 Al, which is incorporated herein in its entirety by reference. In the example method (e.g., CTM, CTM+ or combined CTM and CTM+), a guidance map is generated by optimizing a grayscale image with respect to a performance metric (e.g., EPE, sidelobe etc.) related to lithography. The method can be used to generate an optimized curvilinear mask pattern, which includes curvilinear polygons traced from the grayscale image.

To reduce the runtime of a full-chip mask generation with an aforementioned method, a machine learning based approach can be used, as discussed in PCT patent publication number WO 2018215188 Al, which is incorporated herein in its entirety by reference. For example, a machine learning model can be trained to predict the grayscale image corresponding to an optimized mask pattern using DCNN framework. The predicted grayscale image is very close to a “ground truth,” hence with only a small number of iterations (e.g., less than the iterations needed in the inverse lithography solution) a final curvilinear mask pattern can be generated.

The aforementioned CTM and CTM+techniques involve iterative optimization using grid-based pattern modification. Such grid-based modification may generate different CTM for a target pattern if the grid locations of the target pattern change. Also, as commonly known, inverse lithography has the problem of producing multiple solutions. These solutions may have small or noticeably large differences (e.g., in SRAFs shapes and placements), but may all be considered as acceptable solutions when judged by lithographic performance (DOF, PVB, etc.).

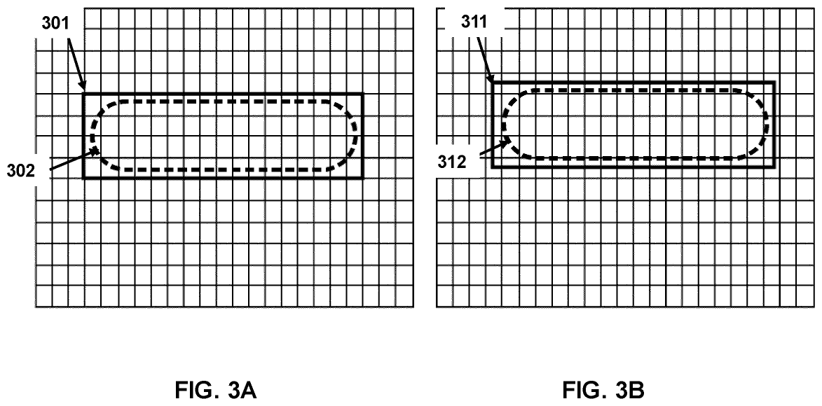

FIGS. 3A-3B illustrate example pattern shifting with respect to a grid causing grid-dependency error. The FIGS. 3A and 3B show, a predicted contour 301/311 (dotted) and input contour 302/312 (e.g., design or desired contour). In FIG. 3A, the entire input contour 301 is on the grid, however in FIG. 3B, a portion of the input contour 311 is off-grid e.g., at the corner points. This can cause a difference between model predicted contours 302 and 312. In an embodiment, e.g., Lithography Manufacturability Check (LMC) or OPC applications, the same pattern may be presented repeatedly at different locations on the grid, and it is desired to have an invariant model prediction, regardless of the pattern's position. However, the models can hardly achieve a perfect shift-invariance. Some ill-conditioned model may give large contour difference in pattern shifts.

In an embodiment, a Grid Dependency (GD) error may be measured as follows. To measure the GD error, the pattern and a gauge along the contour are shifted together in a sub-pixel step. For example, for pixel size=14 nm, the pattern/gauge may be shifted by 1 nm per step along x- and/or y-direction. With each shift, a model predicted CD along the gauge is measured. Then, the variance in the set of model predicted CDs indicates the grid dependency error. Such differences in predicted contours may not be acceptable from a user's point of view. For the same target pattern, customers, OPC engineers or other patterning process related users may prefer to use the same mask to ensure better control on process variation.

The grid dependency problem may extend to the application of the inverse lithography such as used to generate CTM and CTM+. As a CTM/CTM+ generation process goes through iterative optimization to generate results (grayscale mask map and/or curvilinear mask in correspondence), the results for the same target patterns may become more and more different during the optimization due to the effect of the model grid dependency, and due to other treatments in CTM/CTM+ that might cause additional grid dependency, in each iterative steps. The grid dependency problem may also extend to the application of the machine learning based methods used for speeding up e.g., Sub-Resolution Assistant Feature (SRAF) generation. For example, as different solutions exist in ground truth data itself, it causes the machine learning model training difficult to converge to better model with lower RMS from the ground truth result. Also, machine learning based methods are also source of grid dependency, when they are applied to predict results. In the present disclosure, a method (e.g., 400 or 900) is presented to reduce the variation in mask patterns corresponding to similar target patterns that may be caused due to grid dependency, and thus improve the consistency.

In some of the existing methods for generating mask patterns involves predicting assist features (e.g., SRAFs) using a trained machine learning model (e.g., convolutional neural network (CNN)). However, for training purposes, ground truth data that is generated using existing processes (e.g., CTM/CTM+) may comprise different assist features for similar patterns. When such inconsistent ground truth data is used for training, it may cause the machine learning model to predict averaged assist features. For instance, an undesirable cross assist feature may be a result of averaging a horizontal and a vertical candidate assist feature at a location of a target pattern. This causes ambiguity in assist feature extraction thereby affecting an accuracy of the mask pattern.

According to the present disclosure, mechanisms are provided herein to train and use a sequence-to-sequence machine learning model to predict the assist features. In some embodiments, the training data comprises geometric information of target features so that the trained model can predict properties of the assist features directly, thus advantageously avoiding the grid dependency issue, avoiding the averaging effect in convolutional neural network (CNN), and negligible ambiguity in creating assist features. Another advantages effect being the sequence-to-sequence model generated assist features when employed in a mask pattern create good process window (comparable to the ground truth data). Also, the runtime can be better compared than current CNN-based training approaches. Furthermore, SRAFs herein are generated in sequence, as such earlier generated SRAFs are leveraged as constraints for a later generated SRAFs to automatically satisfy certain constraints such as mask manufacturing related constraints.

The sequence-to-sequence training of models involves converting sequences of inputs (e.g., target pattern information) to sequences of outputs (e.g., SRAFs). The sequence-to-sequence model comprises a first neural network (e.g., an encoder) that converts each input item into a corresponding hidden vector containing the item and its context (e.g., an output from a previous step). The sequence-to-sequence model also includes a second neural network (e.g., a decoder) that reverses hidden vector generated by the first neural network to an output item. The second neural network also uses a previous output as the input context. In an embodiment, the first neural network and the second neural network can be integrated into a single model.

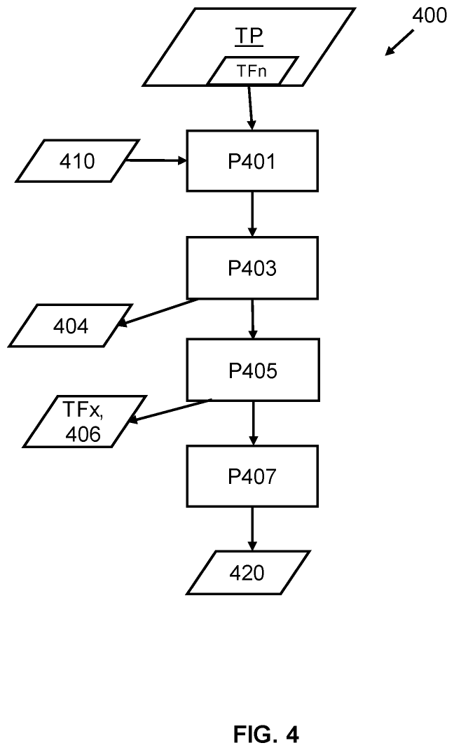

FIG. 4 is a flow chart of an example method 400 for training a sequence-to-sequence machine learning (ML) model to generate sub-resolution assist features (SRAFs) for a mask according to an embodiment of the present disclosure. An exemplary implementation of the method 400 includes process P401-P407, discussed in detail below.

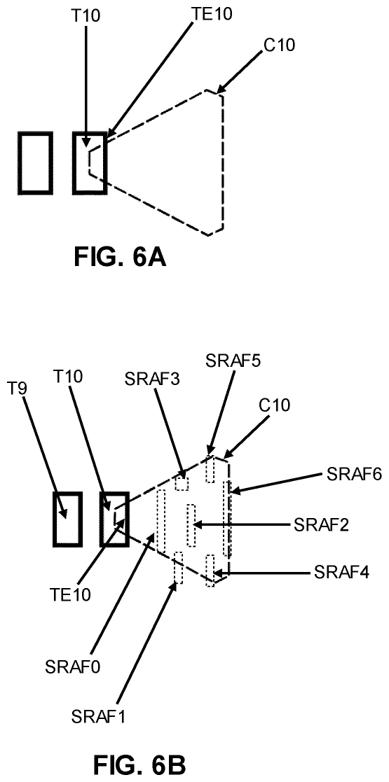

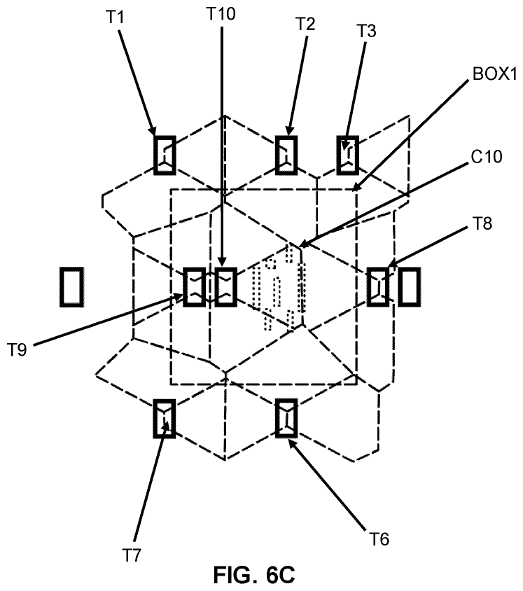

Process P401 involves obtaining training data comprising a target pattern TP having a plurality of target features TFn (e.g., TF1, TF2, TF3, . . . , TFn), and ground truth data including reference sub-resolution assist features (SRAFs) 410 corresponding to the target pattern TP. In an embodiment, the training data may be obtained by associating target edges with one or more reference SRAFs of 410. For example, FIG. 6B (discussed in detail later in the disclosure) illustrates associating reference SRAFs with a target edge. In an embodiment, each target edge of the plurality of target features TFn is associated with one or more reference SRAFs of the reference SRAFs 410 in the ground truth.

Process P403 involves partitioning the target pattern TP into a plurality of cells 404, each cell containing a target edge of the target feature TF. For example, a first cell includes a first edge of a first target feature TF1, and a second cell includes a second edge of the first target feature TF1, a third cell includes a third edge of a second target feature TF2, and so on. In an embodiment, a target edge (e.g., TF1) may be associated with one or more reference SRAFs. For example, the one or more reference SRAFs of 410 associated with a target edge are at locations inside and/or at the boundary of the cell containing the target edge under consideration.

It will be appreciated that the present disclosure is not limited to any specific partitioning mechanism, approach, method, algorithm or process. In an embodiment, the partitioning of the target pattern TP is performed such that each cell has a certain relationship with the selected point or location on the target pattern. In an embodiment, the relationship can be an equivalence relationship (e.g., symmetry) that is satisfied by each cell. In an embodiment, the relationship may be represented as a function between the selected location and a boundary, for example, a minimum distance between a boundary of each cell to the selected location. Such relationship can be used to determine boundaries of each cell that results in partitioning of the target pattern TP. In an embodiment, the selected location is a center of a target edge, or any user defined points on the target patterns.

In an embodiment, the partitioning of the portion of the target pattern TP layout may be based on geometric partitioning (e.g., using a Voronoi method), where boundaries of each cell of the plurality of cells 404 are determined based on a distance between a boundary of the cell and the selected location on the target edge. In an embodiment, the boundaries of each cell of the plurality of cells 404 are determined such that points in each cell are closest to the given location than other locations within the target pattern.

In an embodiment, partitioning of the target pattern TP may involve: selecting a location or a point (e.g., a midpoint of an edge) on each target edge of the plurality of target features TFn; and dividing, based on the selected points, the target pattern TP into the plurality of cells 404. For example, partitioning of the target pattern TP involves using the selected points as seeds according to a Voronoi partitioning method to generate a plurality of Voronoi cells.

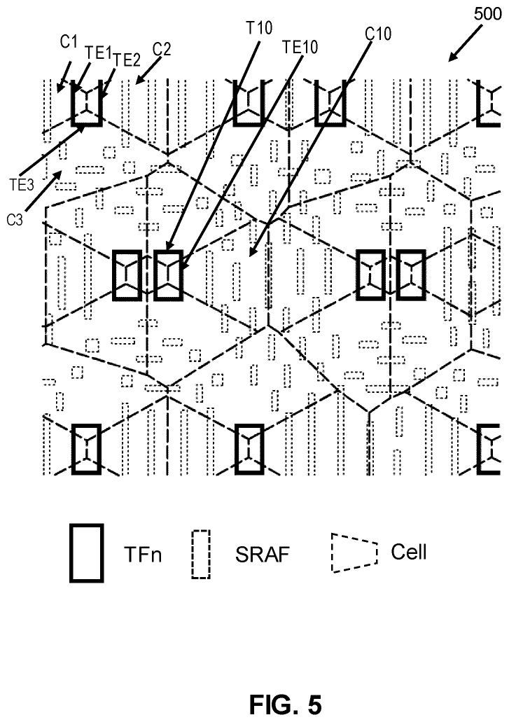

In an embodiment, an input vector may be generated, where the input vector comprises the geometric information (e.g., location, width, length, distances, etc.) of the target features TFn. In an embodiment, the geometric information comprises distance between edges of target features and the target feature under consideration, widths of the target features, etc. For example, in FIG. 5, for target feature T10, TE10 is a target edge under consideration, the SRAFs in C10 is associated with T10, and T10 may be characterized by TE10 and its neighboring target edges (e.g. TE1, TE2, TE3, . . . ). So, for the TE10 target edge, nearby TEn's relatively position to TE10 may be the input vector. The input vector is further input to a machine learning model for training purposes. However, this discussion is merely exemplary; any other suitable form or information can be used as inputs without departing from the scope of the present disclosure. During the training process, the one or more reference SRAFs of 410 associated with each of the target edges within the target pattern TP are used as ground truth for model generated SRAFs at the output.

FIG. 5 illustrates an exemplary partitioning of a target pattern 500 of a design layout, according to an embodiment. The target pattern comprises a plurality of target features TFn. Each target feature has target edges. For partitioning of the target pattern 500, all the target edges may be collected, and its center (or any other suitable location in other embodiments) may be used as seeds for generating a plurality of cells. For example, based on the seeds, the target pattern 500 is divided into a plurality of Voronoi cells such that each target edge has a unique Voronoi cell associated therewith.

As an example, a target feature includes target edges TE1, TE2, and TE3 and its center may be used as seeds to generate Voronoi cells such as C1, C2, and C3, respectively. A center of the target edge TE1 provides the seed for a Voronoi cell C1. The target edge TE1 is at least partially in the Voronoi cell C1. The target edge TE2 provides the seed for a Voronoi cell C2. The target edge TE2 is at least partially in the Voronoi cell C2. The target edge TE3 provides the seed for a Voronoi cell C3. The target edge TE3 is at least partially in the Voronoi cell C3. Similarly, the target edge TE10 provides the seed for a Voronoi cell C10. The target edge TE10 is at least partially in the Voronoi cell C10. Accordingly, each Voronoi cell is associated with a target edge. It can be understood that the present partitioning is only exemplary and other partitioning methods that do not cause grid dependency issues may be employed herein.

The example in FIG. 5 also shows SRAFs placed around each target features. As an example, the SRAFs are shown as dotted rectangles for illustration purposes only and does not limit the scope of the present disclosure. In other examples, curved SRAFs, a combination of rectangular and curved SRAFs, or SRAFs of other shapes and sizes may be used. In an embodiment, the SRAFs serve as reference SRAFs for training a ML model using sequence-to-sequence ML algorithm. For example, according to an embodiment, each target edge may be associated with a subset of reference SRAFs within one or more Voronoi cells around a target edge under consideration (e.g., the target edge TE10 and SRAFs in the cell C10). In an embodiment, such partitioned target pattern, geometric information of target features and corresponding reference SRAFs is used for training the ML model, as described further below.

Referring back to FIG. 4, process P405 involves assigning, to each target edge of the target pattern TP, geometric information 406 (e.g., location, length, width, etc.) of a subset of target features TFx within one or more cells surrounding a target edge under consideration. In an embodiment, assigning of the geometric information 406 involves determining the geometric information 406 of the subset of target features TFx neighboring to the target edge under consideration. In one embodiment, the subset of target features TFx may be features that are at least partially within one or more cells surrounding the target edge under consideration. However, the present disclosure is not limited thereto. In an embodiment, an input vector comprising the geometric information 406 associated with each of the target edges within the target pattern TP may be generated. In an embodiment, the input vector may be appended to include ground truth data or the ground truth data may be provided, at the output, separately from the input vector. In the ground truth data each target edge may be associated with one or more reference SRAFs of 410, as discussed earlier.

In an embodiment, the geometric information 406 may be determined by identifying the subset of target features TFx that are at least partially within the one or more cells in a selected area around the target edge under consideration. For example, the selected area may be an area (e.g., circular shaped, rectangular shaped, etc. area within the target pattern with target edge as a center of the area) that characterizes a range of influence of the neighboring target feature on the SRAFs generation for the target edge under consideration. For example, such neighboring target features may affect the shape, size or other geometric properties of the SRAFs to be estimated.

In an embodiment, determining of the geometric information 406 involves placing a bounding box around the target edge of interest, and selecting the one or more cells of the plurality of cells 404 within the bounding box. Further, the subset of target features TFx that are at least partially within the one or more cells may be identified. The subset of target features TFx may serve as neighboring features of the target edge under consideration that affect geometry of the SRAFs around the target edge under consideration.

In an embodiment, the geometric information 406 may include distances between the target edge under consideration and each target feature of the subset of target features TFx within the target pattern TP. In an embodiment, the geometric information 406 may include a width, and/or a length of each target feature of the subset of target features TFx. In an embodiment, the geometric information 406 may include a location of each target feature of the subset of target features TFx.

FIG. 6A illustrates an exemplary cell C1O associated with a target feature T10. As discussed earlier, the center point of the target edge TE10 serves as a guiding point for determining a cell boundary of the Voronoi cell C10. According to the Voronoi method, each point within the boundary is closer to the center point of the target edge TE10 than to the center point of any other target edges. In an embodiment, reference target features SRAFs may be collected that fall in or at the boundary of the cell C1O and associate the target edge TE10 with those SRAFs.

FIG. 6B illustrates exemplary references SRAFs (e.g., SRAF0, SRAF1, SRAF2, SRAF3, SRAF4, SRAF5, SRAF6) assigned to the target edge TE10. In an embodiment, geometric information of each of the reference SRAF0-SRAF6 may be associated with the target edge TE10, the geometric information including such as width, length, distance from each other, distance from target edge, etc.. Such target edge TE10 and the associated reference SRAFs or SRAFs information may be used for training the ML model. For example, during training, the ML model may predict SRAFs for the target edge TE10. The predicted SRAFs will be compared with the reference SRAF0-SRAF6. Furthermore, for training purposes, each target edge is also associated with geometric information of neighboring target features. The geometric information of the neighboring target features is used as input to the ML model to predict the SRAFs.

FIG. 6C illustrates how neighboring target features of a target edge may be selected and geometric information associated with these neighboring target features may be determined, according to an embodiment. In the present example, the neighboring target features may be selected by placing a bounding box BOX1 (e.g., shaped as a rectangle, a square, a circle, a free from or other geometric shapes) around the target edge of the target feature T10. In an embodiment, the bounding box BOX1 may be determined based on preset heuristic rules, or a user-defined. For ground truth data, each target edge (e.g., TE10) and its Voronoi cell (e.g., C10) is associated with the reference SRAFs in the cell (e.g., C10) of the target edge (e.g., TE10). The SRAFs generation for the cell (e.g., C10) will be affected by nearby Voronoi cells. So, the target edges in those nearby cells may be used as context (e.g., an input) by the machine learning in its generation of SRAFs. In the present example, “nearby cells” may be Voronoi cells that are at least partially in the bounding box BOX1 or within a certain ambit or margin around the bounding box BOX1.

In the example shown, the bounding box BOX1 includes several Voronoi cells. For each of the cells included in the bounding box BOX1, the corresponding target edge or the target feature may be used as a context for generating the SRAFs for an edge. For example, the target features in the nearby cells may be TI, T2, T3, T6, T7, T8, and T9. For each of target features T1-T3, and T6-T9, geometric information, such as their length, width, distances between each other, distance to the edge TE10, etc., may be extracted and included in the input of the ML model being trained. The ML model uses the geometric information to generate the SRAFs for the target edge (e.g., TE10). The generated SRAFs can be compared with the reference SRAFs (e.g., SRAF0-SRFA6 in FIG. 6B) associated with the cell (e.g., C1O). Based on the comparison, model parameters (e.g., encoder-decoder weights) may be adjusted to cause the generated SRAFs to match the reference SRAFs, as further discussed below. For example, if the generated SRAFs is less than a threshold matching percentage with the corresponding reference SRAFs, model parameter weights may be adjusted using a gradient decent method or other weight adjustment method related to a machine learning process.

Although the examples in FIGS. 5 and 6A-6C illustrate rectangular shaped target features, a person of ordinary skill in the art can understand that the present disclosure is not limited to a particular shape of a target feature or SRAFs. The ML model 420 may be trained using curvilinear shaped target features and curvilinear shaped reference SRAFs to predict curvilinear shaped SRAFs.

Process P407 involves training, using a sequence-to-sequence machine learning algorithm, the geometric information 406 and the ground truth, a ML model 420 to generate SRAFs that satisfy a matching threshold with respect to the reference SRAFs 410. In an embodiment, the ML model 420 after training may be referred as the trained ML model.

In an embodiment, the ML model 420 may be a recurrent neural network (RNN) configured to handle sequential input data of variable length. In an embodiment, sequential input data refers to position-based sequence of target features and/or SRAFs. The ML model 420 (e.g., RNN) is configured to handle variable input vector having a variable length, where each target edge has different geometry information associated with neighboring target features. The ML model 420 also generates the output vector that may have a variable length, where different number of SRAFs may be generated having different positions around the target edge under consideration. Typically, recurrent neural network is a neural network that has an internal memory. When the recurrent neural network makes a decision, it considers both the current and previous input (information is stored in the internal memory). On the contrary, in a typical feed-forward neural network, information is only passed forward in one direction, for example, from an input layer through hidden layers to an output layer of the neural network. It has no memory of the input.

In an embodiment, the ML model 420 may be an encoder-decoder of a Long-Short Term Memory (LSTM) architecture, an encoder-decoder of a gated recurrent unit architecture, or a transformer neural network. For example, LSTM units have feedback connections that may be used as hidden layers in RNN, the LSTM cells can process single data points but also entire sequence of data. As another example, Gated Recurrent Units (GRU) may be used as the hidden layer's nodes in the RNN. In an embodiment, a transformer consists of an encoder and a decoder. Instead of using a memory structure as RNN, it uses a multi-head attention structure to collect information from all the other target patterns in the sequenced input.

In an embodiment, the training process may involve providing the geometric information 406 of the subset of target features TFx to the ML model 420 to predict, in a sequence, geometry of SRAFs for each target edge of the target pattern TP. The predict SRAFs may be compared with the one or more reference SRAFs of 410 related to respective target edges of the target pattern TP. Based on the comparison, model parameters (e.g., weights) of the ML model 420 may be adjusted to cause the predicted SRAFs to be within a matching threshold with respect to the reference SRAFs 410 in the ground truth.

In an embodiment, adjusting of the model parameters may involve generating output from the ML model 420 in a sequential manner for each target edge. The generated output may be compared with the reference SRAFs 410 to determine whether the generated output is within the matching threshold with respect to the reference SRAFs 410. Responsive to the generated output not matching the reference SRAFs 410, values of the model parameters may be adjusted to cause the output to be within the matching threshold.

In an embodiment, the generating of the output involves determining, by the ML model 420, geometry of a first assist feature corresponding to a first reference SRAF of the reference SRAFs 410. For example, the output may be generated by a decoder of the ML model 420. Further, based on the first assist feature as input (e.g., to a decoder of the ML model 420), the ML model 420 may determine geometry of a second assist feature that correspond to a second reference SRAF of the reference SRAFs 410. Similarly, based on the first and second assist features as input (e.g., to a decoder of the ML model 420), the ML model 420 may determine geometry of a third assist feature that correspond to a third reference SRAF of the reference SRAFs 410.

In an embodiment, adjusting of the model parameters involves comparing the geometry of the first assist feature with the first reference SRAF; comparing the geometry of the second assist feature with the second reference SRAF; comparing the geometry of the third assist feature with the third reference SRAF; and determining, based on the comparisons, whether geometry of each of the first, second, and third assist features is within the matching threshold of the first, second, and third reference SRAFs, respectively. Responsive to any of the first, second and third assist features not matching the respective reference SRAFs 410, adjusting values of the model parameters.

In an embodiment, adjusting of the model parameters involves determining a gradient of a cost function employed in training the ML model 420 with respect to the model parameters; and adjusting, using the gradient as a guide, values of the model parameters to minimize or maximize the cost function to cause the generated output to match the reference SRAFs 410. In an embodiment, the cost function is a function of a difference between the geometry of ML-generated SRAFs and the reference SRAFs 410.

In mask patterns, SRAF shapes have constraints (e.g., manufacturing limitation) associated therewith, as such the ML model is desired to consider them. An advantageous effect of the training process herein is that it automatically trains the ML model 420 to consider the SRAF constraints such as shape constraints (e.g., a rectangle SRAF or square SRAF and corresponding length limitations) and MRC constraints (e.g., an SRAF to another SRAF, an SRAF to a target space/width, etc.).

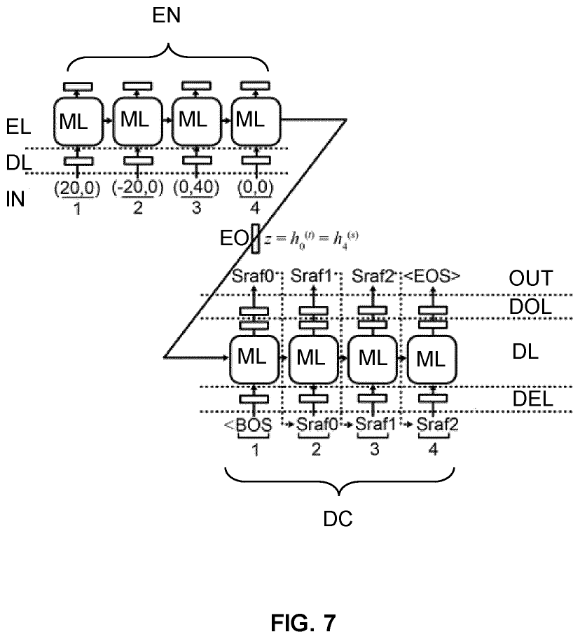

FIG. 7 illustrates an exemplary LSTM model comprising an encoder EN and a decoder DC and configured to predict SRAFs according to an embodiment of the present disclosure. The encoder EN comprises input layers DL configured to receive input IN, which may be position based sequence of target features and associated geometric information. For example, the positions may be centers of target edges used to generate Voronoi cells. The input layer is further connected to an encoder layer EL, which encodes each item of the input in a sequence to generate encoded output EO, also referred as hidden state vector or intermediate output vectors hᵢ^{(s)}. The encoded output EO is passed to the decoder DC. The decoder includes a decoder embedded layer configured to receive the encoded output EO. The decoder also includes a decoder layer configured to decode the encoded output EO to generate assist features (e.g., SRAFs) in a sequential manner. For example, a first assist feature SRAF0 is generated, which is used included as a part of an input EO to generate a second assist feature SRAF1. Similarly, SRAF1 used as input to generate the next output SRAF2, and so on. The decoded output OUT containing the generated assist features SRAF0-SRAF2 may be outputted by a decoder output layer DL.

As discussed earlier, the input IN can be of variable length. The output OUT will not be averaged, rather SRAFs are decided by the decoder layer NL directly. The output will comprise, for example, location, width, length information of each SRAF. As the output OUT is generated step by step in a sequence, the outputted SRAFs will advantageously and automatically incorporate some relations or constraints (e.g., size, distance, or other MRC related constraints) between each other.

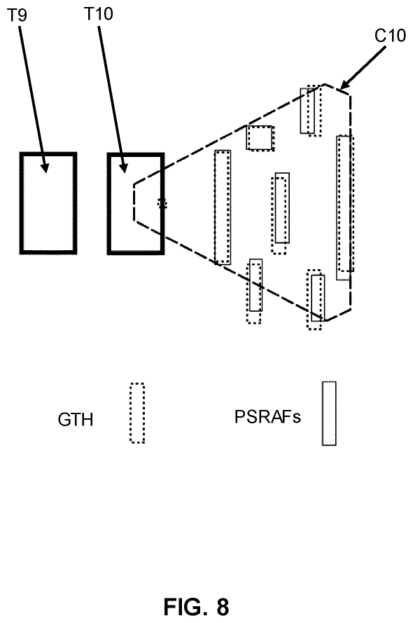

FIG. 8 illustrates exemplary output of the trained machine learning model generated for a target pattern. Only a single cell C10 of a partitioned target pattern is shown for illustration purposes. The trained ML model generated assist features PSRAFs are overlapped with the reference SRAFs of cell C10 for comparison purposes. As shown, although the generated assist features PSRAFs do not exactly match or overlap with reference SRAFs, the matching is considered within a desired threshold. Also, as discussed herein, the rectangular shaped SRAFs are only exemplary and do not limit the scope of the present disclosure. In an embodiment, curved target features may be used as input, and curved SRAFs may be generated as output.

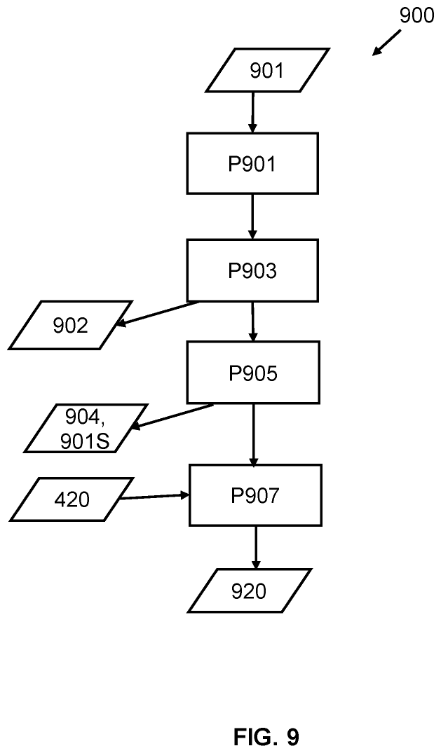

FIG. 9 is an exemplary flow chart of a method 900 for determining assist features (e.g., SRAF) for any design layout including one or more target patterns in accordance with an embodiment of the present disclosure. In an embodiment, the method 900 includes several steps or process and when executed (e.g., via a processor or a computer hardware system) generates sub-resolution assist features (SRAFs) for a mask pattern corresponding to a desired pattern (e.g., the target pattern) to be printed on a substrate.

In an embodiment, the method 900 includes generating sub-resolution assist features (SRAFs) via a trained sequence-to-sequence machine learning (ML) model using geometric information of target features. For example, a mask pattern including the SRAFs may be generated for one or more target patterns of a memory circuitry. Further, a mask with the generated mask pattern may be used to print the target patterns on a substrate.

In an embodiment, the method 900 employs a trained sequence-to-sequence ML model (e.g., trained by the method 400 discussed herein) such as LSTM encoder-decoder, GRU encoder-decoder, transformer, etc. to predict SRAFs for any design layout. The application of the ML model to predict SRAFs involves partitioning a pattern into a plurality of cells (e.g., Voronoi cells). The ML model uses geometric information of target features directly used as input. This can advantageously eliminate grid dependency issues associated with existing approaches of generating SRAFs. For each target edge, SRAFs are predicted in sequence (e.g., as illustrated in FIGS. 7 and 8). During prediction, the ML automatically applies constraints from an earlier predicted SRAF in a next SRAF decision. In an embodiment, SRAFs are clustered based on position, width, length, or other geometric properties of the SRAFs. An exemplary implementation of the method 900 is further discussed in detail using processes P901-P907 below.

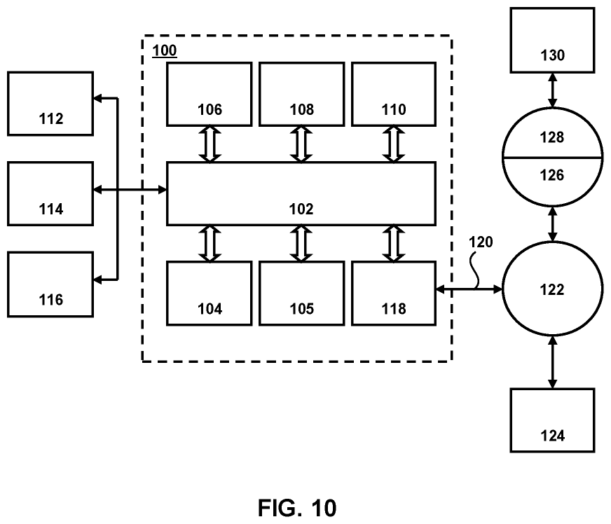

Process P901 involves obtaining a target pattern 901 comprising a plurality of target features. In an embodiment, each target feature of the plurality of target features comprises a plurality of target edges. Additionally, a trained sequence-to-sequence machine leaning (ML) model 420 configured to determine sub-resolution assist features (SRAFs), for the target pattern 901 may be obtained (e.g., retrieved from a memory of the processor 104 in FIG. 10). For example, the ML model 420 is trained according to the method 400, discussed above and stored in the memory of the processor 104.

Process P903 involves partitioning the target pattern 901 into a plurality of cells 902 using each of the target edges as reference so that each cell includes a portion of a target edge of a target feature. The partitioning process may be similar to the process P403 discussed herein. In an embodiment, partitioning of the target pattern 901 involves selecting a location or a point (e.g., a midpoint of an edge) on or about each target edge of the plurality of target features; and dividing, based on the selected points, the target pattern 901 into the plurality of cells 902. For example, partitioning of the target pattern 901 involves partitioning the target pattern 901 using the selected points as seeds to a Voronoi partitioning method to generate a plurality of Voronoi cells.

Process P905 involves determining, for a target edge of the plurality of target edges, geometric information 904 of a subset of target features 901S, e.g., features that are at least partially within a subset of cells of the plurality of cells 902. In an embodiment, a separate subset of target features may be determined for each of the target edges. In an embodiment, the subset of cells may be cells of the plurality of cells 902 that are within a desired range of the target edge within the target pattern 901. In an embodiment, determining of the geometric information 904 involves identifying the subset of target features 901S from the target pattern 901 that are at least partially within the subset of cells in a selected area around the target edge. The selected area providing a range of influence of neighboring target features on the SRAF generation for the target edge.

In an embodiment, the geometric information 904 may be determined by identifying the subset of target features 901S that are at least partially within the one or more cells in a selected area around the target edge under consideration. For example, the selected area may be any area that characterizes a range of influence of the neighboring target feature on the SRAF generation for the target edge under consideration. The range can be determined in any suitable manner that is well known in the art.

In an embodiment, determining of the geometric information 904 involves positioning a bounding box (e.g., BOX1 in FIG. 6C) around the target edge of interest, and selecting the one or more cells of the plurality of cells 902 within the bounding box. Further, the subset of target features 901S that are at least partially within the one or more cells may be identified. The subset of target features 901S may serve as neighboring features of the target edge under consideration that affect geometry of the SRAFs around the target edge under consideration.

In an embodiment, the geometric information 904 may include distances between the target edge under consideration and each target feature of the subset of target features 9015 within the target pattern 901. In an embodiment, the geometric information 904 may include a width, and/or a length of each target feature of the subset of target features 901S. In an embodiment, the geometric information 904 may include a location of each target feature of the subset of target features 901S.

In an embodiment, the geometric information 904 is provided in the form of an input vector having a variable length, as different target edges may be associated with different neighboring target features and thus the corresponding inputs have varying variable lengths. The input vector may be further provided to the ML model 420.

Process P907 involves determining, using the geometric information 904 as input to the ML model 420, SRAFs 920 to be placed around the target edge. In an embodiment, the SRAFs 920 is determined in a sequential manner. For example, determining of the SRAFs 920 involves determining, by the ML model 420, geometry of a first assist feature that automatically satisfies shape constraints and mask rule check (MRC) constraints associated therewith. Based on the first assist feature, the ML model 420 determines geometry of a second assist feature that automatically satisfies the shape constraints and MRC, or other constraints, between the first assist feature and the second assist feature. Based on the first and second assist features, the ML model 420 determines geometry of a third assist feature that automatically satisfies the shape constraints and MRC between the third assist feature and the first assist feature and/or the second assist feature. In an embodiment, the geometric information 904 is determined for all the target edges of the plurality of target features within the target pattern 901.

In an embodiment, the method 900 may be further extended to determine a process window of a patterning process based on the target pattern 901 and the predicted SRAFs 920 of the target pattern 901.

In an embodiment, the method 900 may be further extended to generate a mask pattern by placing the SRAFs 920 associated with each target edge of the plurality of target features around the respective target edge. For example, the method 900 may be integrated with existing mask generation processes comprising an optical proximity correction (OPC) process. For example, a mask pattern comprising SRAFs 920 may be used as an initial pattern, where the OPC process involves modifying the mask pattern to determine an optical proximity corrected mask pattern. In an embodiment, the mask pattern is modified such that a performance metric of the patterning process is improved. For example, improving the performance metric can be minimizing an edge placement error between the target pattern and a simulated pattern generated by the simulation of the patterning process, minimizing a number of extra and insufficient printing of mask features compared to the target patterns, minimizing a CD error between the simulated pattern and the target pattern, or combinations thereof. It will be appreciated that any other suitable OPC process or mechanism of improving a performance metric can be used without departing from the scope of the present disclosure.

Details of techniques and models used to transform a patterning device pattern into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, 2010-0180251 and 2011-0099526, the disclosure of each which is hereby incorporated by reference in its entirety.

As lithography nodes keep shrinking, more and more complicated patterning device pattern (interchangeably referred as a mask herein for better readability) are required (e.g., curvilinear masks). The present method may be used in key layers with DUV scanners, EUV scanners, and/or other scanners. The method according to the present disclosure may be included in different aspect of the mask optimization process including source mask optimization (SMO), mask optimization, and/or OPC. For example, a source mask optimization process is described in U.S. Pat. No. 9,588,438 titled “Optimization Flows of Source, Mask and Projection Optics”, which is hereby incorporated in its entirety by reference.

In an embodiment, a patterning device pattern is a curvilinear mask including curvilinear SRAFs having polygonal shapes, as opposed to that in Manhattan patterns having rectangular or staircase like shapes. A curvilinear mask may produce more accurate patterns on a substrate compared to a Manhattan pattern. However, the geometry of curvilinear SRAFs, their locations with respect to the target patterns, or other related parameters may create manufacturing restrictions, since such curvilinear shapes may not be feasible to manufacture. Hence, such restrictions may be considered by a designer during the mask design process. A detailed discussion on the limitation and challenges in manufacturing a curvilinear mask is provided in “Manufacturing Challenges for Curvilinear Masks” by Spence, et al., Proceeding of SPIE Volume 10451, Photomask Technology, 1045104 (16 Oct. 2017); doi: 10.1117/12.2280470, which is incorporated herein by reference in its entirety.

Optical Proximity Correction (OPC) is a photolithography enhancement technique commonly used to compensate for image errors due to diffraction and process effects. Existing model-based OPC usually consists of several steps, including: (i) derive wafer target pattern including rule retargeting, (ii) place sub-resolution assist features (SRAFs), and (iii) perform iterative corrections including model simulation (e.g., by calculating intensity map on a wafer). The most time consuming parts of the model simulation are model-based SRAF generation and cleanup based on mask rule check (MRC), and simulation of mask diffraction, optical imaging, and resist development. The present method 900 can, for example, expediate the SRAF generation and MRC process thus improving the existing technology.

In an embodiment, the methods discussed herein may be provided as a computer program product or a non-transitory computer readable medium having instructions recorded thereon, the instructions when executed by a computer implementing the operation of the methods 400 and 900 discussed above. An example computer system 100 in FIG. 10 includes a non-transitory computer-readable media (e.g., memory) comprising instructions that, when executed by one or more processors (e.g., 104), cause operations including steps of the methods 400 or 900 discussed herein.

According to present disclosure, the combination and sub-combinations of disclosed elements constitute separate embodiments. For example, a first combination includes preparing training data by partitioning a target pattern and associated each edge of the target pattern to a subset of reference SRAFs. Based on the training data, a machine learning model may be trained using a sequence-to-sequence machine learning method. The sub-combination may include the partitioning the target pattern into Voronoi cells. In another sub-combination, the associating of each target edge may be based on a bounding box of desired size and shape drawn within the target pattern. In another example, the combination includes generating SRAFs for any target pattern using the trained machine learning model. In a sub-combination, the generated SRAFs may be further used to generate a mask pattern.

FIG. 10 is a block diagram that illustrates an exemplary computer system 100 configured to assist in implementing methods and flows disclosed herein in accordance with an embodiment of the present disclosure. Computer system 100 includes a bus 102 or other communication mechanism for communicating information, and a processor 104 (or multiple processors 104 and 105) coupled with bus 102 for processing information. Computer system 100 also includes a main memory 106, such as a random access memory (RAM) or other dynamic storage device, coupled to bus 102 for storing information and instructions to be executed by processor 104. Main memory 106 also may be used for storing temporary variables or other intermediate information during execution of instructions to be executed by processor 104. Computer system 100 further includes a read only memory (ROM) 108 or other static storage device coupled to bus 102 for storing static information and instructions for processor 104. A storage device 110, such as a magnetic disk or optical disk, is provided and coupled to bus 102 for storing information and instructions.

Computer system 100 may be coupled via bus 102 to a display 112, such as a cathode ray tube (CRT) or flat panel or touch panel display for displaying information to a computer user. An input device 114, including alphanumeric and other keys, is coupled to bus 102 for communicating information and command selections to processor 104. Another type of user input device is cursor control 116, such as a mouse, a trackball, or cursor direction keys for communicating direction information and command selections to processor 104 and for controlling cursor movement on display 112. This input device typically has two degrees of freedom in two axes, a first axis (e.g., x) and a second axis (e.g., y), that allows the device to specify positions in a plane. A touch panel (screen) display may also be used as an input device.

According to one embodiment, portions of the process may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may also be employed to execute the sequences of instructions contained in main memory 106. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, optical or magnetic disks, such as storage device 110. Volatile media include dynamic memory, such as main memory 106. Transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 104 for execution. For example, the instructions may initially be borne on a magnetic disk of a remote computer. The remote computer can load the instructions into its dynamic memory and send the instructions over a telephone line using a modem. A modem local to computer system 100 can receive the data on the telephone line and use an infrared transmitter to convert the data to an infrared signal. An infrared detector coupled to bus 102 can receive the data carried in the infrared signal and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 also desirably includes a communication interface 118 coupled to bus 102. Communication interface 118 provides a two-way data communication coupling to a network link 120 that is connected to a local network 122. For example, communication interface 118 may be an integrated services digital network (ISDN) card or a modem to provide a data communication connection to a corresponding type of telephone line. As another example, communication interface 118 may be a local area network (LAN) card to provide a data communication connection to a compatible LAN. Wireless links may also be implemented. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through local network 122 to a host computer 124 or to data equipment operated by an Internet Service Provider (ISP) 126. ISP 126 in turn provides data communication services through the worldwide packet data communication network, now commonly referred to as the “Internet” 128. Local network 122 and Internet 128 both use electrical, electromagnetic or optical signals that carry digital data streams. The signals through the various networks and the signals on network link 120 and through communication interface 118, which carry the digital data to and from computer system 100, are example forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, local network 122 and communication interface 118. One such downloaded application may provide for the illumination optimization of the embodiment, for example. The received code may be executed by processor 104 as it is received, and/or stored in storage device 110, or other non-volatile storage for later execution. In this manner, computer system 100 may obtain application code in the form of a carrier wave.

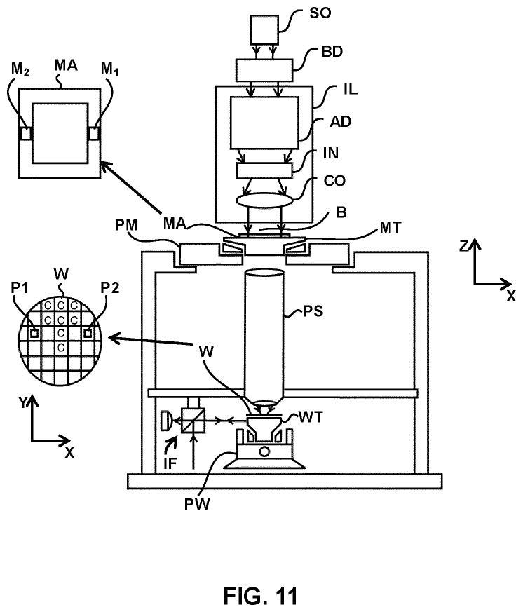

FIG. 11 depicts an exemplary lithographic projection apparatus in conjunction with the techniques described herein can be utilized in accordance with an embodiment of the present disclosure. The apparatus comprises:
an illumination system IL, to condition a beam B of radiation. In this particular case, the illumination system also comprises a radiation source SO;
a first object table (e.g., patterning device table) MT provided with a patterning device holder to hold a patterning device MA (e.g., a reticle), and connected to a first positioner to accurately position the patterning device with respect to item PS;
a second object table (substrate table) WT provided with a substrate holder to hold a substrate W (e.g., a resist-coated silicon wafer), and connected to a second positioner to accurately position the substrate with respect to item PS;
a projection system (“lens”) PS (e.g., a refractive, catoptric or catadioptric optical system) to image an irradiated portion of the patterning device MA onto a target portion C (e.g., comprising one or more dies) of the substrate W.

As depicted herein, the apparatus is of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander Ex, for example. The illuminator IL may comprise adjusting means AD for setting the outer and/or inner radial extent (commonly referred to as a-outer and a-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

It should be noted with regard to FIG. 11 that the source SO may be an integral part of, e.g., within the housing of, the lithographic projection apparatus (as is often the case when the source SO is a mercury lamp, for example), but that it may also be remote from the lithographic projection apparatus, the radiation beam that it produces being led into the apparatus (e.g., with the aid of suitable directing mirrors); this latter scenario is often the case when the source SO is an excimer laser (e.g., based on KrF, ArF or F₂ lasing).

The beam PB subsequently intercepts the patterning device MA, which is held on a patterning device table MT. Having traversed the patterning device MA, the beam B passes through the lens PL, which focuses the beam B onto a target portion C of the substrate W. With the aid of the second positioning means (and interferometric measuring means IF), the substrate table WT can be moved accurately, e.g. so as to position different target portions C in the path of the beam PB. Similarly, the first positioning means can be used to accurately position the patterning device MA with respect to the path of the beam B, e.g., after mechanical retrieval of the patterning device MA from a patterning device library, or during a scan. In general, movement of the object tables MT, WT will be realized with the aid of a long-stroke module (coarse positioning) and a short-stroke module (fine positioning), which are not explicitly depicted in FIG. 11. However, in the case of a stepper (as opposed to a step-and-scan tool) the patterning device table MT may just be connected to a short stroke actuator, or may be fixed.

The depicted tool can be used in two different modes:
In step mode, the patterning device table MT is kept essentially stationary, and an entire patterning device image is projected in one go (i.e., a single “flash”) onto a target portion C. The substrate table WT is then shifted in the x and/or y directions so that a different target portion C can be irradiated by the beam PB;
In scan mode, essentially the same scenario applies, except that a given target portion C is not exposed in a single “flash”. Instead, the patterning device table MT is movable in a given direction (the so-called “scan direction”, e.g., the y direction) with a speed v, so that the projection beam B is caused to scan over a patterning device image; concurrently, the substrate table WT is simultaneously moved in the same or opposite direction at a speed V=Mv, in which M is the magnification of the lens PL (typically, M=¼ or ⅕). In this manner, a relatively large target portion C can be exposed, without having to compromise on resolution.

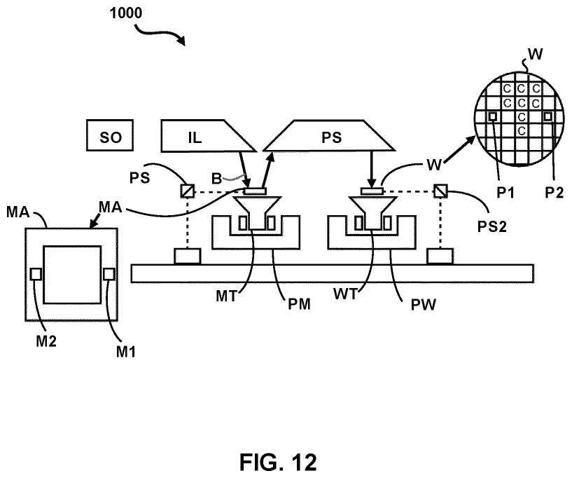

FIG. 12 depicts another exemplary lithographic projection apparatus 1000 in accordance with an embodiment of the present disclosure. Apparatus 1000 includes:
a source collector module SO to provide radiation.
an illumination system (illuminator) IL configured to condition a radiation beam B (e.g. EUV radiation) from the source collector module SO.
a support structure (e.g. a mask table) MT constructed to support a patterning device (e.g. a mask or a reticle) MA and connected to a first positioner PM configured to accurately position the patterning device;
a substrate table (e.g. a wafer table) WT constructed to hold a substrate (e.g. a resist coated wafer) W and connected to a second positioner PW configured to accurately position the substrate; and
a projection system (e.g. a reflective projection system) PS configured to project a pattern imparted to the radiation beam B by patterning device MA onto a target portion C (e.g. comprising one or more dies) of the substrate W.

As here depicted, the apparatus 1000 is of a reflective type (e.g. employing a reflective mask). It is to be noted that because most materials are absorptive within the EUV wavelength range, the patterning device may have multilayer reflectors comprising, for example, a multi-layer stack of molybdenum and silicon. In one example, the multi-stack reflector has a 40 layer pairs of Molybdenum and Silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Referring to FIG. 12, the illuminator IL receives an extreme ultra violet radiation beam from the source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. The source collector module SO may be part of an EUV radiation system including a laser, not shown in FIG. 12, for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser is not considered to form part of the lithographic apparatus and the radiation beam is passed from the laser to the source collector module with the aid of a beam delivery system comprising, for example, suitable directing mirrors and/or a beam expander. In other cases the radiation source may be an integral part of the source collector module, for example when the radiation source is a discharge produced plasma EUV generator, often termed as a DPP radiation source.

The illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B is incident on the patterning device (e.g., mask) MA, which is held on the support structure (e.g., mask table) MT, and is patterned by the patterning device. After being reflected from the patterning device (e.g. mask) MA, the radiation beam B passes through the projection system PS, which focuses the beam onto a target portion C of the substrate W. With the aid of the second positioner PW and position sensor PS2 (e.g. an interferometric device, linear encoder or capacitive sensor), the substrate table WT can be moved accurately, e.g. so as to position different target portions C in the path of the radiation beam B. Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus 1000 could be used in at least one of the following modes:
1. In step mode, the support structure (e.g. mask table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.
2. In scan mode, the support structure (e.g. mask table) MT and the substrate table WT are scanned synchronously while a pattern imparted to the radiation beam is projected onto a target portion C (i.e. a single dynamic exposure). The velocity and direction of the substrate table WT relative to the support structure (e.g. mask table) MT may be determined by the (de-)magnification and image reversal characteristics of the projection system PS.
3. In another mode, the support structure (e.g. mask table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

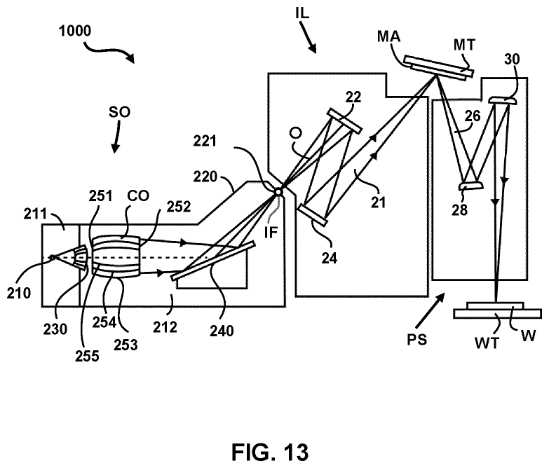

FIG. 13 shows the apparatus 1000 in more detail, including the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma radiation source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing an at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure, as known in the art.

The collector chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the dot-dashed line ‘O’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the Figures, for example there may be 1-6 additional reflective elements present in the projection system PS than shown in FIG. 13.

Collector optic CO, as illustrated in FIG. 13, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type is desirably used in combination with a discharge produced plasma radiation source.

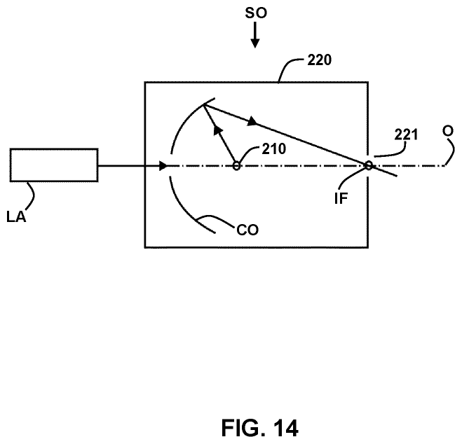

Alternatively, the source collector module SO may be part of an LPP radiation system as shown in FIG. 14. A laser LAS is arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

The concepts disclosed herein may simulate or mathematically model any generic imaging system for imaging sub wavelength features, and may be especially useful with emerging imaging technologies capable of producing wavelengths of an increasingly smaller size. Emerging technologies already in use include EUV (extreme ultra violet) lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

Although specific reference may be made in this text to the use of embodiments in the manufacture of ICs, it should be understood that the embodiments herein may have many other possible applications. For example, it may be employed in the manufacture of integrated optical systems, guidance and detection patterns for magnetic domain memories, liquid-crystal displays (LCDs), thin film magnetic heads, micromechanical systems (MEMs), etc. The skilled artisan will appreciate that, in the context of such alternative applications, any use of the terms “reticle”, “wafer” or “die” herein may be considered as synonymous or interchangeable with the more general terms “patterning device”, “substrate” or “target portion”, respectively. The substrate referred to herein may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create, for example, a multi-layer IC, so that the term substrate used herein may also refer to a substrate that already contains multiple processed layers.

In the present document, the terms “radiation” and “beam” as used herein encompass all types of electromagnetic radiation, including ultraviolet radiation (e.g. with a wavelength of about 365, about 248, about 193, about 157 or about 126 nm) and extreme ultra-violet (EUV) radiation (e.g. having a wavelength in the range of 5-20 nm), as well as particle beams, such as ion beams or electron beams.

The terms “optimizing” and “optimization” as used herein refers to or means adjusting a patterning apparatus (e.g., a lithography apparatus), a patterning process, etc. such that results and/or processes have more desirable characteristics, such as higher accuracy of projection of a design pattern on a substrate, a larger process window, etc. Thus, the term “optimizing” and “optimization” as used herein refers to or means a process that identifies one or more values for one or more parameters that provide an improvement, e.g. a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

Aspects of the invention can be implemented in any convenient form. For example, an embodiment may be implemented by one or more appropriate computer programs which may be carried on an appropriate carrier medium which may be a tangible carrier medium (e.g. a disk) or an intangible carrier medium (e.g. a communications signal). Embodiments of the invention may be implemented using suitable apparatus which may specifically take the form of a programmable computer running a computer program arranged to implement a method as described herein. Thus, embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g. within a data center or geographically), or otherwise differently organized. The functionality described herein may be provided by one or more processors of one or more computers executing code stored on a tangible, non-transitory, machine readable medium. In some cases, third party content delivery networks may host some or all of the information conveyed over networks, in which case, to the extent information (e.g., content) is said to be supplied or otherwise provided, the information may be provided by sending instructions to retrieve that information from a content delivery network.

Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device.

The reader should appreciate that the present application describes several inventions. Rather than separating those inventions into multiple isolated patent applications, these inventions have been grouped into a single document because their related subject matter lends itself to economies in the application process. But the distinct advantages and aspects of such inventions should not be conflated. In some cases, embodiments address all of the deficiencies noted herein, but it should be understood that the inventions are independently useful, and some embodiments address only a subset of such problems or offer other, unmentioned benefits that will be apparent to those of skill in the art reviewing the present disclosure. Due to costs constraints, some inventions disclosed herein may not be presently claimed and may be claimed in later filings, such as continuation applications or by amending the present claims. Similarly, due to space constraints, neither the Abstract nor the Summary sections of the present document should be taken as containing a comprehensive listing of all such inventions or all aspects of such inventions.

1. A non-transitory computer-readable medium comprising instructions stored therein that, when executed by one or more processors, cause the one or more processors to perform a method of generating a mask pattern, the method comprising:
obtaining (i) a target pattern comprising a plurality of target features, wherein each of the plurality of target features comprises a plurality of target edges, and (ii) a trained sequence-to-sequence machine leaning (ML) model configured to determine sub-resolution assist features (SRAFs) for the target pattern;
determining, for a target edge of the plurality of target edges, geometric information of a subset of target features surrounding the target edge; and
determining, using the geometric information as input to the ML model, SRAFs to be placed around the target edge.
   2. The medium of clause 1, further comprising:
partitioning, using each of the target edge as a reference, of the target pattern into a plurality of cells so that each cell includes a portion of a target edge of a target feature.
   3. The medium of clause 2, wherein partitioning of the target pattern comprises:
selecting a point on each edge of the plurality of target features; and dividing, based on the selected points, the target pattern into the plurality of cell.
   4. The medium of clause 3, wherein partitioning of the target pattern comprises:
partitioning the target pattern using the selected points as seeds to a Voronoi partitioning method to generate a plurality of Voronoi cells.
   5. The medium of clause 2, wherein determining of the geometric information of the subset of target features comprises:
identifying the subset of target features that are at least partially within a subset of cells of the plurality of cells, wherein the subset of cells is within a desired range of the target edge within the target pattern.
   6. The medium of clause 5, wherein determining of the geometric information comprises:
identifying the subset of target features that are at least partially within the subset of cells in a selected area around the target edge, the selected area providing a range of influence of neighboring target features on the SRAF generation for the target edge.
   7. The medium of clause 6, wherein determining of the geometric information comprises:
selecting, by placing a bounding box around the target edge, the subset of cells of the plurality of cells; and
identifying the subset of target features that are at least partially within the subset of cells, the subset of target features serving as neighboring features of the target edge that affect geometry of the SRAFs around the target edge.
   8. The medium of any of clauses 1-7, wherein determining of the geometric information comprises:
identifying distances between the target edge and each target feature of the subset of target features within the target pattern.
   9. The medium of any of clauses 1-8, wherein determining of the geometric information comprises:
identifying a width, and/or a length of each target feature of the subset of target features.
   10. The medium of any of clauses 1-9, wherein determining of the geometric information comprises:
identifying a location of each target feature of the subset of target features.
   11. The medium of any of clauses 1-10, wherein determining of the SRAFs comprises determining the SRAFs in a sequential manner.
   12. The medium of any of clauses 11, wherein determining of the SRAFs comprises:
determining, by the ML model, the geometry of assist features that satisfies mask rule check (MRC) constraints, wherein the ML model generates the SRAFs in a sequential manner such that an earlier SRAF having satisfied shaped constraint is used to generate subsequent SRAFs causing the generated SRAFs to automatically satisfies the MRC constraints.
   13. The medium of clause 12, wherein determining of the SRAFs comprises:
determining, by the ML model, geometry of a first assist feature that automatically satisfies shape constraints and MRC constraints associated therewith;
determining, by the ML model based on the first assist feature, geometry of a second assist feature that automatically satisfying the shape constraints and MRC between the first assist feature and the second assist feature; and
determining, by the ML model based on the first and second assist features, geometry of a third assist feature that automatically satisfying the shape constraints and MRC between the third assist feature and the first assist feature and/or the second assist feature.
   14. The medium of any of clauses 1-13, wherein determining the geometric information further comprises generating an input vector having a variable length caused by association of the target edge with neighboring target features, the input vector configured to be provided to the ML model.
   15. The medium of any of clauses 1-14, the instructions further comprises: determining a process window of a patterning process based on the target pattern and the SRAFs of the target pattern.
   16. The medium of any of clauses 1-15, wherein determining the geometric information for the target edge comprises determining the geometric information for all the target edges of the plurality of target features within the target pattern.
   17. The medium of any of clauses 1-16, the instructions further comprises:
generating a mask pattern by placing the SRAFs associated with each target edge of the plurality of target pattern around the respective target edge.
   18. The medium of any of clauses 1-17, further comprises instructions for training the ML model, the training process comprises:
obtaining training data comprising a sample target pattern having a plurality of target features, and ground truth data including reference sub-resolution assist features corresponding to the sample target pattern;
assigning, to each target edge of the sample target pattern, geometric information of a subset of target features surrounding a target edge under consideration; and
training, using a sequence-to-sequence machine learning algorithm, the geometric information and the ground truth, a ML model to generate SRAFs in a sequential manner to satisfy a matching threshold with respect to the reference SRAFs.
   19. The medium of clause 18, wherein training data is provided as input data or input vector to the ML model, the input data or the input vector comprises at least one of: a sizes of the subset of target features, distances between the target edge under consideration and the subset of target features, and locations of the subset of target features.
   20. The medium of clause 18, further comprising:
partitioning, using each of the target edge as a reference, of the sample target pattern into a plurality of cells so that each cell includes a portion of a target edge of a target feature.
   21. The medium of clause 20, wherein partitioning of the sample target pattern comprises:
selecting a point on each target edge of the plurality of target features; and
dividing, based on the selected points, the sample target pattern into the plurality of cell.
   22. The medium of clause 21, wherein partitioning of the sample target pattern comprises:
partitioning the sample target pattern using the selected points as seeds to a Voronoi partitioning method to generate a plurality of Voronoi cells.
   23. The medium of any of clauses 20-22, wherein assigning of the geometric information comprises:
determining the geometric information of the subset of target features neighboring to the target edge under consideration, the subset of target features being within one or more cells surrounding the target edge under consideration; and
generating an input vector comprising the geometric information associated with each of the target edges within the sample target pattern.
   24. The medium of clause 23, wherein determining of the geometric information comprises:
identifying the subset of target features that are at least partially within the one or more cells in a selected area around the edge of interest, the selected area providing a range of influence of the neighboring target feature on the SRAF generation for the target edge under consideration.
   25. The medium of clause 24, wherein determining of the geometric information comprises:
selecting, by placing a bounding box around the target edge of interest, the one or more cells of the plurality of cells; and
identifying the subset of target features that are at least partially within the one or more cells, the subset of target features serving as neighboring features of the edge of interest that affect geometry of the SRAFs around the target edge under consideration.
   26. The medium of any of clauses 18-25, wherein determining of the geometric information comprises:
identifying distances between the target edge under consideration and each target feature of the subset of target features within the sample target pattern.
   27. The medium of any of clauses 18-26, wherein determining of the geometric information comprises:
identifying a width, and/or a length of each target feature of the subset of target features.
   28. The medium of any of clauses 18-27, wherein determining of the geometric information comprises:
identifying a location of each target feature of the subset of target features.
   29. The medium of any of clauses 20-28, wherein obtaining of the training data comprises:
associating each target edge of the plurality of target features with one or more reference SRAFs of the reference SRAFs in the ground truth, the one or more reference SRAFs being at locations inside the cell containing the target edge under consideration; and
providing, the ground truth, the geometric information of the one or more reference SRAFs associated with each of the target edges within the sample target pattern.
   30. The medium of any of clauses 29, wherein the training comprises:
providing the geometric information of the subset of target features to the ML model to predict in a sequence geometry of SRAFs for each target edge of the sample target pattern; and
comparing the predict SRAFs with the one or more reference SRAFs related to respective target edges of the sample target pattern;
adjusting model parameters of the ML model to cause the predicted SRAFs to be within the matching threshold with respect to the reference SRAFS in the ground truth.
   31. The medium of clause 30, wherein adjusting of the model parameters comprises:
generating output from the ML model in a sequential manner for each target edge;
comparing the generated output with the reference SRAFs to determine whether the generated output is within the matching threshold with respect to the reference SRAFs; and
responsive to the generated output not matching the reference SRAFs, adjusting values of the model parameters to cause the output to be within the matching threshold.
   32. The medium of clause 31, wherein generating of the output comprises:
determining, by the ML model, geometry of a first assist feature corresponding to a first reference SRAF of the reference SRAFs;
determining, by the ML model based on the first assist feature, geometry of a second assist feature that correspond to a second reference SRAF of the reference SRAFs; and
determining, by the ML model based on the first and second assist features, geometry of a third assist feature that correspond to a second reference SRAF of the reference SRAFs.
   33. The medium of clause 32, wherein adjusting of the model parameters comprises:
comparing the geometry of the first assist feature with the first reference SRAF;
comparing the geometry of the second assist feature with the second reference SRAF;
comparing the geometry of the third assist feature with the third reference SRAF; and
determining, based on the comparisons, whether geometry of each of the first, second, and third assist features is within the matching threshold of the first, second, and third reference SRAFs, respectively; and
responsive to any of the first, second and third assist features not matching the respective reference SRAFs, adjusting values of the model parameters.
   34. The medium of clause 33, wherein adjusting of the model parameters comprises:
determining a gradient of a cost function employed in training the ML model with respect to the model parameters; and
adjusting, using the gradient as a guide, values of the model parameters to minimize or maximize the cost function to cause the generated output to match the reference SRAFs.
   35. The medium of clause 34, wherein the cost function is a function of a difference between the geometry of ML-generated SRAFs and the reference SRAFs.
   36. The medium of any of clauses 1-35, wherein the ML model is a recurrent neural network configured to handle sequential input data.
   37. The medium of any of clauses 1-36, wherein the ML model is an encoder-decoder of a long short term memory architecture, an encoder-decoder of a gated recurrent unit architecture, or a transformer neural network.
   38. A non-transitory computer-readable medium configured for training a trained sequence-to-sequence machine learning (ML) model to generate sub-resolution assist features (SRAFs) for a mask, the medium comprising instructions stored therein that, when executed by one or more processors, cause operations comprising:
obtaining training data comprising a target pattern having a plurality of target features, and ground truth data including reference sub-resolution assist features corresponding to the target pattern;
assigning, to each target edge of the target pattern, geometric information of a subset of target features surrounding a target edge under consideration; and
training, using a sequence-to-sequence machine learning algorithm, the geometric information and the ground truth, a ML model to generate SRAFs in a sequential manner to satisfy a matching threshold with respect to the reference SRAFs.
   39. The medium of clause 38, wherein training data is provided as input data or input vector to the ML model, the input data or the input vector comprises at least one of: sizes of the subset of target features, distances between the target edge under consideration and the subset of target features, and locations of the subset of target features.
   40. The medium of clause 38, further comprising:
partitioning, using each of the target edge as a reference, of the target pattern into a plurality of cells so that each cell includes a portion of a target edge of a target feature.
   41. The medium of clause 40, wherein partitioning of the target pattern comprises:
selecting a point on each target edge of the plurality of target features; and
dividing, based on the selected points, the target pattern into the plurality of cells.
   42. The medium of clause 41, wherein partitioning of the target pattern comprises:
partitioning the target pattern using the selected points as seeds to a Voronoi partitioning method to generate a plurality of Voronoi cells.
   43. The medium of any of clauses 40-42, wherein assigning of the geometric information comprises:
determining the geometric information of the subset of target features neighboring to the target edge under consideration, the subset of target features being within one or more cells surrounding the target edge under consideration; and
generating an input vector comprising the geometric information associated with each of the target edges within the target pattern.
   44. The medium of clause 43, wherein determining of the geometric information comprises:
identifying the subset of target features that are at least partially within the one or more cells in a selected area around the edge of interest, the selected area providing a range of influence of the neighboring target feature on the SRAF generation for the target edge under consideration.
   45. The medium of clause 44, wherein determining of the geometric information comprises:
selecting, by placing a bounding box around the target edge of interest, the one or more cells of the plurality of cells; and
identifying the subset of target features that are at least partially within the one or more cells, the subset of target features serving as neighboring features of the edge of interest that affect geometry of the SRAFs around the target edge under consideration.
   46. The medium of any of clauses 43-45, wherein determining of the geometric information comprises:
identifying distances between the target edge under consideration and each target feature of the subset of target features within the target pattern.
   47. The medium of any of clauses 43-46, wherein determining of the geometric information comprises:
identifying a width, and/or a length of each target feature of the subset of target features.
   48. The medium of any of clauses 43-47, wherein determining of the geometric information comprises:
identifying a location of each target feature of the subset of target features.
   49. The medium of any of clauses 40-48, wherein obtaining of the training data comprises:
associating each target edge of the plurality of target features with one or more reference SRAFs of the reference SRAFs in the ground truth, the one or more reference SRAFs being at locations inside the cell containing the target edge under consideration; and
providing, the ground truth, the geometric information of the one or more reference SRAFs associated with each of the target edges within the target pattern.
   50. The medium of any of clauses 49, wherein the training comprises:
providing the geometric information of the subset of target features to the ML model to predict in a sequence geometry of SRAFs for each target edge of the target pattern; and
comparing the predict SRAFs with the one or more reference SRAFs related to respective target edges of the target pattern;
adjusting model parameters of the ML model to cause the predicted SRAFs to be within the matching threshold with respect to the reference SRAFS in the ground truth.
   51. The medium of clause 50, wherein adjusting of the model parameters comprises:
generating output from the ML model in a sequential manner for each target edge;
comparing the generated output with the reference SRAFs to determine whether the generated output is within the matching threshold with respect to the reference SRAFs; and
responsive to the generated output not matching the reference SRAFs, adjusting values of the model parameters to cause the output to be within the matching threshold.
   52. The medium of clause 51, wherein generating of the output comprises:
determining, by the ML model, geometry of a first assist feature corresponding to a first reference SRAF of the reference SRAFs;
determining, by the ML model based on the first assist feature, geometry of a second assist feature that correspond to a second reference SRAF of the reference SRAFs; and
determining, by the ML model based on the first and second assist features, geometry of a third assist feature that correspond to a second reference SRAF of the reference SRAFs.
   53. The medium of clause 52, wherein adjusting of the model parameters comprises:
comparing the geometry of the first assist feature with the first reference SRAF;
comparing the geometry of the second assist feature with the second reference SRAF;
comparing the geometry of the third assist feature with the third reference SRAF; and
determining, based on the comparisons, whether geometry of each of the first, second, and third assist features is within the matching threshold of the first, second, and third reference SRAFs, respectively; and
responsive to any of the first, second and third assist features not matching the respective reference SRAFs, adjusting values of the model parameters.
   54. The medium of clause 53, wherein adjusting of the model parameters comprises:
determining a gradient of a cost function employed in training the ML model with respect to the model parameters; and
adjusting, using the gradient as a guide, values of the model parameters to minimize or maximize the cost function to cause the generated output to match the reference SRAFs.
   55. The medium of clause 54, wherein the cost function is a function of a difference between the geometry of ML-generated SRAFs and the reference SRAFs.
   56. The medium of any of clauses 38-55, wherein the ML model is a recurrent neural network configured to handle sequential input data.
   57. The medium of any of clauses 38-56, wherein the ML model is an encoder-decoder of a long short term memory architecture, an encoder-decoder of a gated recurrent unit architecture, or a transformer neural network.
   58. The medium of any of clauses 43-57, wherein the input vector has a variable length, wherein each target edge has different geometry information associated with neighboring target features.
   59. The medium of any of clauses 38-58, further comprising generating, using the trained ML model, SRAFs for a given target pattern comprising a plurality of target edges.
   60. The medium of clause 59, generating of the SRAFs for the given target pattern comprises:
determining, for a target edge of the plurality of target edges, geometric information of a subset of target features surrounding a target edge; and
determining, using the geometric information as input to the trained ML model, SRAFs to be placed around the target edge of the given target pattern.
   61. The medium of clause 59, further comprising:
partitioning, using each of the target edge as a reference, of the given target pattern into a plurality of cells so that each cell includes a portion of a target edge of a target feature.
   62. The medium of clause 61, wherein partitioning of the given target pattern comprises: selecting a point on each edge of the plurality of target features; and
dividing, based on the selected points, the given target pattern into the plurality of cell.
   63. The medium of clause 62, wherein partitioning of the given target pattern comprises:
partitioning the given target pattern using the selected points as seeds to a Voronoi partitioning method to generate a plurality of Voronoi cells.
   64. The medium of clause 61, wherein determining of the geometric information of the subset of target features comprises:
identifying the subset of target features that are at least partially within a subset of cells of the plurality of cells, wherein the subset of cells is within a desired range of the target edge within the given target pattern.
   65. The medium of clause 64, wherein determining of the geometric information comprises:
identifying the subset of target features that are at least partially within the subset of cells in a selected area around the target edge, the selected area providing a range of influence of neighboring target features on the SRAF generation for the target edge.
   66. The medium of clause 65, wherein determining of the geometric information comprises:
selecting, by placing a bounding box around the target edge, the subset of cells of the plurality of cells; and
identifying the subset of target features that are at least partially within the subset of cells, the subset of target features serving as neighboring features of the target edge that affect geometry of the SRAFs around the target edge.
   67. A method for generating a mask pattern, the method comprising:
obtaining (i) a target pattern comprising a plurality of target features, wherein each of the plurality of target features comprises a plurality of target edges, and (ii) a trained sequence-to-sequence machine leaning (ML) model configured to determine sub-resolution assist features (SRAFs) for the target pattern;
determining, for a target edge of the plurality of target edges, geometric information of a subset of target features surrounding the target edge; and
determining, using the geometric information as input to the ML model, SRAFs to be placed around the target edge.
   68. The method of clause 67, further comprising:
partitioning, using each of the target edge as a reference, of the target pattern into a plurality of cells so that each cell includes a portion of a target edge of a target feature.
   69. The method of clause 68, wherein partitioning of the target pattern comprises:
selecting a point on each edge of the plurality of target features; and dividing, based on the selected points, the target pattern into the plurality of cell.
   70. The method of clause 69, wherein partitioning of the target pattern comprises:
partitioning the target pattern using the selected points as seeds to a Voronoi partitioning method to generate a plurality of Voronoi cells.
   71. The method of clause 68, wherein determining of the geometric information of the subset of target features comprises:
identifying the subset of target features that are at least partially within a subset of cells of the plurality of cells, wherein the subset of cells is within a desired range of the target edge within the target pattern.
   72. The method of clause 71, wherein determining of the geometric information comprises:
identifying the subset of target features that are at least partially within the subset of cells in a selected area around the target edge, the selected area providing a range of influence of neighboring target features on the SRAF generation for the target edge.
   73. The method of clause 72, wherein determining of the geometric information comprises:
selecting, by placing a bounding box around the target edge, the subset of cells of the plurality of cells; and
identifying the subset of target features that are at least partially within the subset of cells, the subset of target features serving as neighboring features of the target edge that affect geometry of the SRAFs around the target edge.
   74. The method of any of clauses 67-73, wherein determining of the geometric information comprises:
identifying distances between the target edge and each target feature of the subset of target features within the target pattern.
   75. The method of any of clauses 67-74, wherein determining of the geometric information comprises:
identifying a width, and/or a length of each target feature of the subset of target features.
   76. The method of any of clauses 67-75, wherein determining of the geometric information comprises:
identifying a location of each target feature of the subset of target features.
   77. The method of any of clauses 67-76, wherein determining of the SRAFs comprises determining the SRAFs in a sequential manner.
   78. The method of any of clauses 77, wherein determining of the SRAFs comprises:
determining, by the ML model, the geometry of assist features that satisfies mask rule check (MRC) constraints, wherein the ML model generates the SRAFs in a sequential manner such that an earlier SRAF having satisfied shaped constraint is used to generate subsequent SRAFs causing the generated SRAFs to automatically satisfies the MRC constraints.
   79. The method of clause 78, wherein determining of the SRAFs comprises:
determining, by the ML model, geometry of a first assist feature that automatically satisfies shape constraints and MRC constraints associated therewith;
determining, by the ML model based on the first assist feature, geometry of a second assist feature that automatically satisfying the shape constraints and MRC between the first assist feature and the second assist feature; and
determining, by the ML model based on the first and second assist features, geometry of a third assist feature that automatically satisfying the shape constraints and MRC between the third assist feature and the first assist feature and/or the second assist feature.
   80. The method of any of clauses 67-79, wherein determining the geometric information further comprises generating an input vector having a variable length caused by association of the target edge with neighboring target features, the input vector configured to be provided to the ML model.
   81. The method of any of clauses 67-80, further comprises: determining a process window of a patterning process based on the target pattern and the SRAFs of the target pattern.
   82. The method of any of clauses 67-81, wherein determining the geometric information for the target edge comprises determining the geometric information for all the target edges of the plurality of target features within the target pattern.
   83. The method of any of clauses 67-82, further comprises:
generating a mask pattern by placing the SRAFs associated with each target edge of the plurality of target pattern around the respective target edge.
   84. The method of any of clauses 67-83, further comprises training the ML model by:
obtaining training data comprising a sample target pattern having a plurality of target features, and ground truth data including reference sub-resolution assist features corresponding to the sample target pattern;
assigning, to each target edge of the sample target pattern, geometric information of a subset of target features surrounding a target edge under consideration; and
training, using a sequence-to-sequence machine learning algorithm, the geometric information and the ground truth, a ML model to generate SRAFs in a sequential manner to satisfy a matching threshold with respect to the reference SRAFs.
   85. The method of clause 84, wherein training data is provided as input data or input vector to the ML model, the input data or the input vector comprises at least one of: a sizes of the subset of target features, distances between the target edge under consideration and the subset of target features, and locations of the subset of target features.
   86. The method of clause 84, further comprising:
partitioning, using each of the target edge as a reference, of the sample target pattern into a plurality of cells so that each cell includes a portion of a target edge of a target feature.
   87. The method of clause 86, wherein partitioning of the sample target pattern comprises:
selecting a point on each target edge of the plurality of target features; and
dividing, based on the selected points, the sample target pattern into the plurality of cell.
   88. The method of clause 87, wherein partitioning of the sample target pattern comprises:
partitioning the sample target pattern using the selected points as seeds to a Voronoi partitioning method to generate a plurality of Voronoi cells.
   89. The method of any of clauses 86-88, wherein assigning of the geometric information comprises:
determining the geometric information of the subset of target features neighboring to the target edge under consideration, the subset of target features being within one or more cells surrounding the target edge under consideration; and
generating an input vector comprising the geometric information associated with each of the target edges within the sample target pattern.
   90. The method of clause 89, wherein determining of the geometric information comprises:
identifying the subset of target features that are at least partially within the one or more cells in a selected area around the edge of interest, the selected area providing a range of influence of the neighboring target feature on the SRAF generation for the target edge under consideration.
   91. The method of clause 90, wherein determining of the geometric information comprises:
selecting, by placing a bounding box around the target edge of interest, the one or more cells of the plurality of cells; and
identifying the subset of target features that are at least partially within the one or more cells, the subset of target features serving as neighboring features of the edge of interest that affect geometry of the SRAFs around the target edge under consideration.
   92. The method of any of clauses 86-91, wherein determining of the geometric information comprises:
identifying distances between the target edge under consideration and each target feature of the subset of target features within the sample target pattern.
   93. The method of any of clauses 86-91, wherein determining of the geometric information comprises:
identifying a width, and/or a length of each target feature of the subset of target features.
   94. The method of any of clauses 86-93, wherein determining of the geometric information comprises:
identifying a location of each target feature of the subset of target features.
   95. The method of any of clauses 88-94, wherein obtaining of the training data comprises:
associating each target edge of the plurality of target features with one or more reference SRAFs of the reference SRAFs in the ground truth, the one or more reference SRAFs being at locations inside the cell containing the target edge under consideration; and
providing, the ground truth, the geometric information of the one or more reference SRAFs associated with each of the target edges within the sample target pattern.
   96. The method of clause 95, wherein the training comprises:
providing the geometric information of the subset of target features to the ML model to predict, in a sequence, geometry of SRAFs for each target edge of the sample target pattern; and
comparing the predict SRAFs with the one or more reference SRAFs related to respective target edges of the sample target pattern;
adjusting model parameters of the ML model to cause the predicted SRAFs to be within the matching threshold with respect to the reference SRAFS in the ground truth.
   97. The method of clause 96, wherein adjusting of the model parameters comprises:
generating output from the ML model in a sequential manner for each target edge;
comparing the generated output with the reference SRAFs to determine whether the generated output is within the matching threshold with respect to the reference SRAFs; and
responsive to the generated output not matching the reference SRAFs, adjusting values of the model parameters to cause the output to be within the matching threshold.
   98. The method of clause 97, wherein generating of the output comprises:
determining, by the ML model, geometry of a first assist feature corresponding to a first reference SRAF of the reference SRAFs;
determining, by the ML model based on the first assist feature, geometry of a second assist feature that correspond to a second reference SRAF of the reference SRAFs; and
determining, by the ML model based on the first and second assist features, geometry of a third assist feature that correspond to a second reference SRAF of the reference SRAFs.
   99. The method of clause 98, wherein adjusting of the model parameters comprises:
comparing the geometry of the first assist feature with the first reference SRAF;
comparing the geometry of the second assist feature with the second reference SRAF;
comparing the geometry of the third assist feature with the third reference SRAF; and
determining, based on the comparisons, whether geometry of each of the first, second, and third assist features is within the matching threshold of the first, second, and third reference SRAFs, respectively; and
responsive to any of the first, second and third assist features not matching the respective reference SRAFs, adjusting values of the model parameters.
   100. The method of clause 99, wherein adjusting of the model parameters comprises:
determining a gradient of a cost function employed in training the ML model with respect to the model parameters; and
adjusting, using the gradient as a guide, values of the model parameters to minimize or maximize the cost function to cause the generated output to match the reference SRAFs.
   101. The method of clause 100, wherein the cost function is a function of a difference between the geometry of ML-generated SRAFs and the reference SRAFs.
   102. The method of any of clauses 67-101, wherein the ML model is a recurrent neural network configured to handle sequential input data.
   103. The method of any of clauses 67-102, wherein the ML model is an encoder-decoder of a long short term memory architecture, an encoder-decoder of a gated recurrent unit architecture, or a transformer neural network.
   104. A method for training a trained sequence-to-sequence machine learning (ML) model to generate sub-resolution assist features (SRAFs) for a mask, the method comprising:
obtaining training data comprising a target pattern having a plurality of target features, and ground truth data including reference sub-resolution assist features corresponding to the target pattern;
assigning, to each target edge of the target pattern, geometric information of a subset of target features surrounding a target edge under consideration; and
training, using a sequence-to-sequence machine learning algorithm, the geometric information and the ground truth, a ML model to generate SRAFs in a sequential manner to satisfy a matching threshold with respect to the reference SRAFs.
   105. The method of clause 104, wherein training data is provided as input data or input vector to the ML model, the input data or the input vector comprises at least one of: sizes of the subset of target features, distances between the target edge under consideration and the subset of target features, and locations of the subset of target features.
   106. The method of clause 104, further comprising:
partitioning, using each of the target edge as a reference, of the target pattern into a plurality of cells so that each cell includes a portion of a target edge of a target feature.
   107. The method of clause 106, wherein partitioning of the target pattern comprises:
selecting a point on each target edge of the plurality of target features; and
dividing, based on the selected points, the target pattern into the plurality of cells.
   108. The method of clause 107, wherein partitioning of the target pattern comprises:
partitioning the target pattern using the selected points as seeds to a Voronoi partitioning method to generate a plurality of Voronoi cells.
   109. The method of any of clauses 106-108, wherein assigning of the geometric information comprises:
determining the geometric information of the subset of target features neighboring to the target edge under consideration, the subset of target features being within one or more cells surrounding the target edge under consideration; and
generating an input vector comprising the geometric information associated with each of the target edges within the target pattern.
   110. The method of clause 109, wherein determining of the geometric information comprises:
identifying the subset of target features that are at least partially within the one or more cells in a selected area around the edge of interest, the selected area providing a range of influence of the neighboring target feature on the SRAF generation for the target edge under consideration.
   111. The method of clause 110, wherein determining of the geometric information comprises:
selecting, by placing a bounding box around the target edge of interest, the one or more cells of the plurality of cells; and
identifying the subset of target features that are at least partially within the one or more cells, the subset of target features serving as neighboring features of the edge of interest that affect geometry of the SRAFs around the target edge under consideration.
   112. The method of any of clauses 109-111, wherein determining of the geometric information comprises:
identifying distances between the target edge under consideration and each target feature of the subset of target features within the target pattern.
   113. The method of any of clauses 109-112, wherein determining of the geometric information comprises:
identifying a width, and/or a length of each target feature of the subset of target features.
   114. The method of any of clauses 109-113, wherein determining of the geometric information comprises:
identifying a location of each target feature of the subset of target features.
   115. The method of any of clauses 106-114, wherein obtaining of the training data comprises:
associating each target edge of the plurality of target features with one or more reference SRAFs of the reference SRAFs in the ground truth, the one or more reference SRAFs being at locations inside the cell containing the target edge under consideration; and
providing, the ground truth, the geometric information of the one or more reference SRAFs associated with each of the target edges within the target pattern.
   116. The method of any of clauses 115, wherein the training comprises:
providing the geometric information of the subset of target features to the ML model to predict in a sequence geometry of SRAFs for each target edge of the target pattern; and
comparing the predict SRAFs with the one or more reference SRAFs related to respective target edges of the target pattern;
adjusting model parameters of the ML model to cause the predicted SRAFs to be within the matching threshold with respect to the reference SRAFS in the ground truth.
   117. The method of clause 116, wherein adjusting of the model parameters comprises:
generating output from the ML model in a sequential manner for each target edge;
comparing the generated output with the reference SRAFs to determine whether the generated output is within the matching threshold with respect to the reference SRAFs; and
responsive to the generated output not matching the reference SRAFs, adjusting values of the model parameters to cause the output to be within the matching threshold.
   118. The method of clause 117, wherein generating of the output comprises:
determining, by the ML model, geometry of a first assist feature corresponding to a first reference SRAF of the reference SRAFs;
determining, by the ML model based on the first assist feature, geometry of a second assist feature that correspond to a second reference SRAF of the reference SRAFs; and
determining, by the ML model based on the first and second assist features, geometry of a third assist feature that correspond to a second reference SRAF of the reference SRAFs.
   119. The method of clause 118, wherein adjusting of the model parameters comprises: comparing the geometry of the first assist feature with the first reference SRAF;
comparing the geometry of the second assist feature with the second reference SRAF;
comparing the geometry of the third assist feature with the third reference SRAF; and
determining, based on the comparisons, whether geometry of each of the first, second, and third assist features is within the matching threshold of the first, second, and third reference SRAFs, respectively; and
responsive to any of the first, second and third assist features not matching the respective reference SRAFs, adjusting values of the model parameters.
   120. The method of clause 119, wherein adjusting of the model parameters comprises:
determining a gradient of a cost function employed in training the ML model with respect to the model parameters; and
adjusting, using the gradient as a guide, values of the model parameters to minimize or maximize the cost function to cause the generated output to match the reference SRAFs.
   121. The method of clause 120, wherein the cost function is a function of a difference between the geometry of ML-generated SRAFs and the reference SRAFs.
   122. The method of any of clauses 104-121, wherein the ML model is a recurrent neural network configured to handle sequential input data.
   123. The method of any of clauses 104-122, wherein the ML model is an encoder-decoder of a long short term memory architecture, an encoder-decoder of a gated recurrent unit architecture, or a transformer neural network.
   124. The method of any of clauses 109-123, wherein the input vector has a variable length, wherein each target edge has different geometry information associated with neighboring target features.
   125. The method of any of clauses 104-124, further comprising generating, using the trained ML model, SRAFs for a given target pattern comprising a plurality of target edges.
   126. The method of clause 125, generating of the SRAFs for the given target pattern comprises:
determining, for a target edge of the plurality of target edges, geometric information of a subset of target features surrounding a target edge; and
determining, using the geometric information as input to the trained ML model, SRAFs to be placed around the target edge of the given target pattern.
   127. The method of clause 125, further comprising:
partitioning, using each of the target edge as a reference, of the given target pattern into a plurality of cells so that each cell includes a portion of a target edge of a target feature.
   128. The method of clause 127, wherein partitioning of the given target pattern comprises:
selecting a point on each edge of the plurality of target features; and
dividing, based on the selected points, the given target pattern into the plurality of cell.
   129. The method of clause 128, wherein partitioning of the given target pattern comprises:
partitioning the given target pattern using the selected points as seeds to a Voronoi partitioning method to generate a plurality of Voronoi cells.
   130. The method of clause 127Error! Reference source not found., wherein determining of the geometric information of the subset of target features comprises:
identifying the subset of target features that are at least partially within a subset of cells of the plurality of cells, wherein the subset of cells is within a desired range of the target edge within the given target pattern.
   131. The method of clause 130, wherein determining of the geometric information comprises:
identifying the subset of target features that are at least partially within the subset of cells in a selected area around the target edge, the selected area providing a range of influence of neighboring target features on the SRAF generation for the target edge.
   132. The method of clause 131, wherein determining of the geometric information comprises:
selecting, by placing a bounding box around the target edge, the subset of cells of the plurality of cells; and
identifying the subset of target features that are at least partially within the subset of cells, the subset of target features serving as neighboring features of the target edge that affect geometry of the SRAFs around the target edge.

It should be understood that the description and the drawings are not intended to limit the present disclosure to the particular form disclosed, but to the contrary, the intention is to cover all modifications, equivalents, and alternatives falling within the spirit and scope of the inventions as defined by the appended claims.

Modifications and alternative embodiments of various aspects of the inventions will be apparent to those skilled in the art in view of this description. Accordingly, this description and the drawings are to be construed as illustrative only and are for the purpose of teaching those skilled in the art the general manner of carrying out the inventions. It is to be understood that the forms of the inventions shown and described herein are to be taken as examples of embodiments. Elements and materials may be substituted for those illustrated and described herein, parts and processes may be reversed or omitted, certain features may be utilized independently, and embodiments or features of embodiments may be combined, all as would be apparent to one skilled in the art after having the benefit of this description. Changes may be made in the elements described herein without departing from the spirit and scope of the invention as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an” element or “a” element includes a combination of two or more elements, notwithstanding use of other terms and phrases for one or more elements, such as “one or more.” The term “or” is, unless indicated otherwise, non-exclusive, i.e., encompassing both “and” and “or.” Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every. References to selection from a range includes the end points of the range.

In the above description, any processes, descriptions or blocks in flowcharts should be understood as representing modules, segments or portions of code which include one or more executable instructions for implementing specific logical functions or steps in the process, and alternate implementations are included within the scope of the exemplary embodiments of the present advancements in which functions can be executed out of order from that shown or discussed, including substantially concurrently or in reverse order, depending upon the functionality involved, as would be understood by those skilled in the art.

While certain embodiments have been described, these embodiments have been presented by way of example only, and are not intended to limit the scope of the present disclosures. Indeed, the novel methods, apparatuses and systems described herein can be embodied in a variety of other forms; furthermore, various omissions, substitutions and changes in the form of the methods, apparatuses and systems described herein can be made without departing from the spirit of the present disclosures. The accompanying claims and their equivalents are intended to cover such forms or modifications as would fall within the scope and spirit of the present disclosures.

1.-15. (canceled)

16. A non-transitory computer-readable medium comprising instructions stored therein that, when executed by one or more processors, are configured to cause the one or more processors to at least:
obtain (i) a target pattern comprising a plurality of target features, wherein each of the plurality of target features comprises a plurality of target edges, and (ii) a trained sequence-to-sequence machine leaning (ML) model configured to determine sub-resolution assist features (SRAFs) for the target pattern;
determine, for a target edge of the plurality of target edges, geometric information of a subset of target features surrounding the target edge; and
determine, using the geometric information as input to the ML model, SRAFs to be placed around the target edge.

17. The medium of claim 16, wherein the instructions are further configured to cause the one or more processors to partition, using each of the target edge as a reference, the target pattern into a plurality of cells so that each cell includes a portion of a target edge of a target feature.

18. The medium of claim 17, wherein the instructions configured to cause the one or more processors to partition the target pattern are further configured to cause the one or more processors to partition the target pattern using the selected points as seeds to a Voronoi partitioning method to generate a plurality of Voronoi cells.

19. The medium of claim 17, wherein the instructions configured to cause the one or more processors to determine the geometric information are further configured to cause the one or more processors to identify the subset of target features that are at least partially within a subset of cells of the plurality of cells, wherein the subset of cells is within a specified range of the target edge within the target pattern.

20. The medium of claim 16, wherein the instructions configured to cause the one or more processors to determine the geometric information are further configured to cause the one or more processors to identify the subset of target features that are in a selected area around the target edge, the selected area providing a range of influence of neighboring target features on the SRAF generation for the target edge.

21. The medium of claim 16, wherein the instructions configured to cause the one or more processors to determine the geometric information are further configured to cause the one or more processors to identify distances between the target edge and each target feature of the subset of target features within the target pattern.

22. The medium of claim 16, wherein the instructions configured to cause the one or more processors to determine the geometric information are further configured to cause the one or more processors to identify a width, and/or a length of each target feature of the subset of target features.

23. The medium of claim 16, wherein the instructions configured to cause the one or more processors to determine the geometric information are further configured to cause the one or more processors to identify a location of each target feature of the subset of target features.

24. The medium of claim 16, wherein the instructions configured to cause the one or more processors to determine the SRAFs are further configured to cause the one or more processors to determine the SRAFs in a sequential manner.

25. The medium of claim 24, wherein the instructions configured to cause the one or more processors to determine the SRAFs are further configured to cause the one or more processors to determine, by the ML model, geometry of assist features that satisfies one or more mask rule check (MRC) constraints, wherein the ML model generates the SRAFs in a sequential manner such that an earlier SRAF having satisfied a shape constraint is used to generate a subsequent SRAF causing the generated SRAFs to automatically satisfy the one or more MRC constraints.

26. The medium of claim 25, wherein the instructions configured to cause the one or more processors to determine the SRAFs are further configured to cause the one or more processors to:
determine, by the ML model, geometry of a first assist feature that automatically satisfies shape and MRC constraints;
determine, by the ML model based on the first assist feature, geometry of a second assist feature that automatically satisfies a shape constraint and an MRC constraint between the first assist feature and the second assist feature; and
determine, by the ML model based on the first and second assist features, geometry of a third assist feature that automatically satisfies a shape constraint and an MRC constraint between the third assist feature and the first assist feature and/or second assist feature.

27. The medium of claim 16, wherein the instructions configured to cause the one or more processors to determine the geometric information are further configured to cause the one or more processors to generate an input vector having a variable length caused by association of the target edge with neighboring target features, the input vector configured to be provided to the ML model.

28. The medium of claim 16, wherein the instructions configured to cause the one or more processors to determine the geometric information are further configured to cause the one or more processors to determine the geometric information for all the target edges of the plurality of target features within the target pattern.

29. The medium of claim 16, wherein the instructions are further configured to cause the one or more processors to generate a mask pattern by placing the SRAFs associated with each target edge of the plurality of target pattern around the respective target edge.

30. The medium of claim 16, wherein the instructions are further configured to cause the one or more processors to train the ML model, the training comprising:
obtaining of training data comprising a sample target pattern having a plurality of target features, and ground truth data including reference sub-resolution assist features corresponding to the sample target pattern;
assignment, to each target edge of the sample target pattern, of geometric information of a subset of target features surrounding a target edge under consideration; and
training, using a sequence-to-sequence machine learning algorithm and with the geometric information and the ground truth, a ML model to generate SRAFs in a sequential manner to satisfy a matching threshold with respect to the reference SRAFs.

31. A non-transitory computer-readable medium comprising instructions stored therein that, when executed by one or more processors, are configured to cause the one or more processors to at least:
obtain training data comprising a target pattern having a plurality of target features, and ground truth data including reference sub-resolution assist features (SRAFs) corresponding to the target pattern;
assigning, to each target edge of the target pattern, geometric information of a subset of target features surrounding a target edge under consideration; and
training, using a sequence-to-sequence machine learning algorithm with the geometric information and the ground truth, a machine learning model to generate SRAFs in a sequential manner to satisfy a matching threshold with respect to the reference SRAFs.

32. The medium of claim 31, wherein training data is provided as input data or input vector to the ML model, the input data or input vector comprising at least one selected from: sizes of the subset of target features, distances between the target edge under consideration and the subset of target features, and/or locations of the subset of target features.

33. The medium of claim 31, wherein the instructions are further configured to cause the one or more processors to partition, using each of the target edge as a reference, of the target pattern into a plurality of cells so that each cell includes a portion of a target edge of a target feature.

34. The medium of claim 31, wherein the ML model is a recurrent neural network configured to handle sequential input data.

35. The medium of claim 31, wherein the ML model is an encoder-decoder of a long short term memory architecture, an encoder-decoder of a gated recurrent unit architecture, or a transformer neural network.
